(19) United States
(12) Patent Application Publication
(10) Pub. No.: US 2026/0234803 A1
(43) Pub. Date: Aug. 13, 2026

(54) LARGE SCALE SYSTEM FOR ATOMIC LAYER DEPOSITION

(71) Applicant: Forge Nano Inc., Thornton, CO (US)

(72) Inventors: Andrew Broerman, Frederick, CO (US); James Ragonesi, Thornton, CO (US); Brian Evanko, Thornton, CO (US)

(21) Appl. No.: 19/151,599

(22) PCT Filed: Jan. 30, 2024
(86) PCT No.: PCT/US2024/013596

§ 371 Date: Jul. 28, 2025

Related U.S. Application Data
(60) Provisional application No. 63/442,111, filed on Jan. 30, 2023.

(51) Int. Cl. C23C 16/52; C23C 16/455

(52) U.S. Cl. CPC C23C 16/52; C23C 16/45527; C23C 16/45544; C23C 16/45561

(57) ABSTRACT

A system, apparatus, and method of atomic layer deposition (ALD) having an arrangement of components designed to process large quantities of powders that is highly reproducible and accurate. Precursors can be supplied to a reactor by surge vessels that also serve the purpose of vaporizing the liquid precursors. These vessels are allowed to swing in pressure and deliver the precursor to the reactor, and be refilled in-line as necessary without disrupting the manufacturing process.

### RELATED APPLICATIONS

This application claims the priority benefit of U.S. Provisional Patent Application Ser. No. 63/442,111 filed Jan. 30, 2023.

### TECHNICAL FIELD

This invention relates to an apparatus and methods for applying an atomic layer deposition layer to a particulate substrate.

### INTRODUCTION

A goal of atomic layer deposition (ALD) is to deposit, monolayer by monolayer, conformal coating layers on a substrate surface. This can be achieved because classic ALD generally comprises two self-limiting half-reactions, each half-reaction producing a single monolayer of precursor molecules on the substrate surface until the surface is “saturated” or completely coated.

In temporal ALD, the half-reactions are separated sequentially by time-sequenced, alternate dosing of each precursor. In spatial ALD, the half-reactions are separated by zones, and the substrate is transported sequentially from zone to zone. Temporal ALD allows for highly controlled environments where the total surface area of substrate is contained within a singular ALD system. This leads to an opportunity to fine-tune the precursor dosing and purging steps for maximal efficiency and precursor utilization. However, spatial ALD provides for an overall increase in throughput relative to temporal systems because between each precursor gas dosing, spatial ALD requires the substrate to be purged, versus the precursors as is the case with temporal ALD. Temporal ALD requires that any remaining reactive gas be removed to prevent any chemical vapor deposition process (CVD) from occurring. It has been found that the dosing, purging and subsequent pumping times limit the production rate for ALD coated powders since conventional approaches to temporal ALD on powders have been found to be impractical for high-throughput manufacturing. Yet the cost benefits of using batch-based systems to carry out 10's to 100's of ALD cycles remain superior, particularly for lower volume production needs of ~10's of tons per year or lower. As such, there remains an unmet need for a batch or semi-batch ALD system for powders that can be operated more efficiently at an industrial scale.

### SUMMARY OF THE INVENTION

The present invention is a large, batch or semi-batch ALD system for coating powders, hereinafter also referred to as “Lithos”, is designed to coat batches ranging from 10's of kgs-100's of kgs of powder or particulate substrates with monolayers of material using an Atomic Layer Deposition process. This is accomplished by loading the reactor with the substrate and preparing the reactor for the reactive process. An example of which is an aluminum oxide process based upon trimethylaluminum (TMA) and water, a zinc oxide process based upon diethylzinc (DEZ) and water, etc. This involves heating the reactor and purging the system of any residual moisture or undesired gases. Once at proper operating conditions (e.g. for aluminum oxide ALD), the substrate is exposed to the precursors TMA and water in an alternating fashion. Nitrogen purges are used to remove reaction products and unreacted precursor. Since this invention is aimed toward industrial-scale ALD in a production environment, the precursors are supplied to the reactor by surge vessels that also serve the purpose of vaporizing the liquid precursors. These vessels are allowed to swing in pressure and deliver the precursor to the reactor and be refilled in-line as necessary without disrupting the manufacturing process. The surge vessels are typically kept at operating temperature unless it is desired to cool the vessels for maintenance or energy conservation. The pressure of the reactor is also varying with the processing steps. The temperature of the reactor is traditionally kept constant for the processing of the substrate, but the flexibility of the design allows for a swing in temperature during the process as desired. The reactor can be cooled or heated quickly to facilitate loading and unloading of the substrate without exposure to high temperature substrate. Reaction progress is monitored by sampling the reactor outlet gases just before entering the main exhaust pump using a residual gas analyzer. Industry-relevant recipes for coating a variety of substrates have been developed with precursor utilization efficiency in mind, which limits the excess precursor flowing to the vacuum pump and the atmosphere. In cases where excess precursor is desirable for production efficiency, additional abatement systems can be deployed to maintain system up-time and performance.

In one aspect, the invention includes one or more vaporization tanks controlled using a dew point calculator and level sensors.

In another aspect, the invention includes a coaxial rotary union for inlet and outlet of gaseous species such as reactive precursors and reaction byproducts. The coaxial rotary union benefits from customized packing, packing pushers, o-rings, etc. that are required for effective operation of the ALD process, including separation of reactive precursor to avoid CVD while operating industrial processes. This aspect of the invention further includes a filter tree with rotating inlet filter and revolving outlet filters.

In another aspect, the invention includes a multi-pressure residual gas analyzer (RGA) sampling system with valved inlets and orifice gaskets designed to be able to monitor and manage all gaseous species in-line and in real time within the system, independent of pressure state.

In another aspect, the invention includes a sonic backpulse unit to clean inlet and outlet filters simultaneously.

In another aspect, the invention includes a dose pushing using tri-valved control volume in dosing manifold, such that discrete pulses of reactants can be diluted while administered into the reactor to decouple the reactant partial pressure from the system operating pressure by pressurizing inert gas into a known molar content of precursor can be administered into the reactor.

In a further aspect, the invention provides an atomic layer deposition system for exposing a first reactive precursor and a second reactive precursor to a plurality of particles having a known total surface area comprising: a first vaporization vessel (V-120) comprising the first reactive precursor, a first thermal control system having a first thermal controller adapted to control an operating temperature of the first vaporization vessel V-120, and a first pressure transducer PT-124 to measure an operating pressure of the first vaporization vessel V-120; a first volume element (VE-12X) defined by a pipe volume contained between a first computer-controlled valve (XV-122), a second computer-controlled valve (XV-124) and a third computer-controlled valve (XV-102); a second vaporization vessel (V-140) comprising the second reactive precursor and a second thermal controller adapted to control an operating temperature of the second vaporization vessel V-140, and a second pressure transducer PT-144 adapted to measure an operating pressure of the second vaporization vessel V-140; a second volume element (VE-14X) defined as a pipe volume contained between a fourth computer-controlled valve (XV-142), a fifth computer-controlled valve (XV-144) and a sixth computer-controlled valve (XV-104); an inert gas delivery system in fluid communication with both: a first volume element (VE-12X) when the third computer-controlled valve (XV-102) is in an open position, and the second volume element (VE-14X) when the sixth computer-controlled valve (XV-104) is in an open position; and a reactor (R-200) having a gas inlet, a gas outlet, and a gate valve for loading and unloading the plurality of particles having a known total surface area, and having a third thermal control system having a means of controlling the operating temperature of the reactor, and a third pressure transducer to measure the operating pressure of the reactor; wherein the first vaporization vessel V-120 is in fluid communication with the first volume element (VE-12X) when the first computer-controlled valve XV-122 is in an open position, and wherein the second vaporization vessel V-140 is in fluid communication with the second volume element (VE-14X) when the fourth computer-controlled valve XV-142 is in an open position; wherein the first volume element is in fluid communication with the reactor when the second computer-controlled valve is in an open position, and wherein the second volume element is in fluid communication with the reactor when the fifth computer-controlled valve is in an open position; and wherein the second computer-controlled valve and the fifth computer-controlled valve cannot be in an open position simultaneously, wherein the first computer-controlled valve and the third computer-controlled valve cannot be in an open position simultaneously, wherein the fourth computer-controlled valve and the sixth computer-controlled valve cannot be in an open position simultaneously.

Any of the aspects can be further characterized by one or more of the following features: wherein the first vaporization vessel further comprises an inlet port for filling the first reactive precursor, a first liquid level sensor positioned at or near the bottom of the first vaporization vessel, and a first dew point control system in electrical signal communication with the first thermal control system, the first pressure transducer the first liquid level sensor, the third thermal control system, and the third pressure transducer; wherein the second vaporization vessel further comprises an inlet port for filling the second reactive precursor, a second liquid level sensor positioned at or near the bottom of the second vaporization vessel, and a second dew point control system in electrical signal communication with the second thermal control system, the second pressure transducer the second liquid level sensor, the third thermal control system, and the third pressure transducer; further comprising a seventh computer-controlled valve interposed between the inert gas delivery system and the reactor, wherein the seventh computer-controlled valve is able to be modulated between an open state (100%), a closed state (0%), and partial states (1% to 99%); further comprising an eighth computer-controlled valve positioned after the gas outlet of the reactor, wherein the eighth computer-controlled valve is able to be modulated between an open state (100%), a closed state (0%), and partial states (1% to 99%); wherein the gas inlet and gas outlet of the reactor are positioned coaxially to each other; wherein the reactor is rotatable horizontally at a controllable frequency ranging from 0.5 to 30 revolutions per minute, and along the same axis as the coaxial gas inlet and gas outlet, and wherein the coaxial gas inlet and gas outlet rotate with the reactor; wherein the volume of the reactor is at least 25 Liters, at least 50 Liters, at least 100 Liters, or at least 250 Liters; and wherein the volume of each vaporization vessel is 40% to 60% of the volume of the reactor.

In a further aspect, the invention provides a method for applying a coating onto a plurality of particles having a known total surface area in a reactor comprising a sub-cycle comprising the steps of: administering from a dosing source, a first precursor dose into the reactor at a first controlled precursor temperature, which defines the first precursor pressure, for a first time period; terminating the first precursor dose administration and isolating the reactor from the dosing source and vacuum pump, and applying a first static hold for a second time period; administering a first dose push comprising inert gas into the reactor at an inert gas pressure that is at least 100 Torr higher than the first precursor pressure at the first controlled precursor temperature, for a third time period; terminating the first dose administration and isolating the reactor from the dosing source and vacuum, and applying a second static hold for a fourth time period; and repeating the steps of the sub-cycle a first plurality of times, wherein the pressure of the reactor during the fourth time period of each repeated sub-cycle is at least 50 Torr greater than the pressure of the reactor during the fourth time period of each immediately preceding sub-cycle. In a preferred embodiment, the sub-cycles are repeated a second plurality of times to apply a second plurality of ALD cycles on the plurality of particles having a known total surface area. The first plurality is at least two, or 5 or more, or 10 or more, or up to 100 or up to up to 50. Likewise, the second plurality is at least two, or 5 or more, or 10 or more, or up to 100 or up to up to 50.

In another aspect, the invention provides a method for applying an ALD coating onto a plurality of particles having a known total surface area in a reactor operatively connected to a residual gas analyzer (RGA) comprising a sub-cycle comprising the steps of: administering from a dosing source, a first precursor dose into the reactor at a first controlled precursor temperature, which defines the first precursor pressure, for a first time period and independently monitoring the RGA signals of the ALD reaction product and the precursor, wherein the maximum height of the RGA signal of the ALD reaction product is defined as S_{Y} where Y=1, and the first time period is defined as t_{Y} where Y=1, the time between the initial rise of the RGA signal of the ALD reaction product and the initial rise of the RGA signal of the precursor; terminating the first precursor dose administration and isolating the reactor from the dosing source and vacuum pump, and applying a first static hold for a second time period; administering a first dose push comprising inert gas into the reactor at an inert gas pressure that is less than that of the first precursor pressure at the first controlled precursor temperature, for a third time period; terminating the first dose administration and isolating the reactor from the dosing source and vacuum, and applying a second static hold for a fourth time period; and repeating the steps of the sub-cycle for Y times where Y is at least two, and until the product of S_{Y}·t_{Y} during the Yth sub-cycle is <5% of the product of S₁·t_{1·}

Any of the methods of the invention can be further characterized by one or any combination of the following features: wherein the Y sub-cycles are repeated Z times to apply Z ALD cycles on the plurality of particles having a known total surface area; wherein with the second time period and the fourth time period of each Yth sub-cycle are reduced until the summation of ΣS_{Y}·t_{Y·} during any ALD cycle deviates by more than 5% of the summation of ΣS_{Y}·t_{Y·} during the immediately preceding ALD cycle; further comprising a second precursor wherein the Z ALD cycles include the Y sub-cycles of claim 12 as applied to the first precursor, followed by the X sub-cycles as applied to the second precursor; wherein the first precursor comprises a metal, semi-metal, non-metal or metalloid element that forms the cation of the ALD coating; wherein the second precursor comprises oxygen, nitrogen, fluorine, carbon, phosphorous or sulfur and forms the anion of the ALD coating. X, Y, or Z, can be, for example, 2 or more, 4 or more, 10 or more, up to 100 or up to 50 (these can be independent variables (for example, Y is not always equal to Z); in the broader aspects, these ranges are not limiting).

In some embodiments, the methods can be carried out in the apparatus described herein. The invention includes, but is not limited to, any of these aspects. The invention includes any of these aspects either alone or in any combination and/or in combination with any of the features described herein. The invention also includes any of the apparatus, systems, components, methods, and combination of apparatus, systems, components, and/or methods, described herein. The invention also includes methods of coating powders including any of the descriptions herein. The invention is not limited to the full set of components but includes any combination of steps and/or components described in the words or drawings. The invention may be described by the term “comprising” meaning including, and may instead be described by the narrower terms “consisting essentially of” which excludes components that materially affect the invention, or “consisting of.”

### BRIEF DESCRIPTION OF THE DRAWINGS

FIG. 1A shows a rotary batch ALD apparatus and system for coating powders at an industrial scale.

FIG. 1B shows a rotary semi-batch/semi-continuous ALD apparatus and system comprising a series of rotary batch units for coating powders at higher throughput semi-continuously.

FIG. 2A: Reactive/Auxiliary Gas Subassembly PID and Dosing Manifold PID

FIG. 2B: Valve nomenclature from PID

FIG. 3: First Vaporization Vessel Apparatus and System PID

FIG. 4: Second Vaporization Vessel Apparatus and System PID

FIG. 5: Process for sub-dosing a reactive precursor into an industrial-scale Lithos system: 1) isolate reactor from vacuum; 2) begin precursor dose from Vaporization Vessel to Reactor; 3) isolate Vaporization Vessel to refill from precursor source; 4) dose push to flush Volume Element 14X; 5) Static hold for sub-dose hold period; 6) Blowback pulse and dose purge.

FIG. 6: Pressure traces corresponding to the sub-dosing process of FIG. 5, showing the pressures at the vaporization vessel (PT-144), between the dosing manifold and the reactor (PT-190), and between the reactor and the active abatement system (PT-200).

FIG. 7: Pressure traces (top) corresponding to the process sequence (bottom) of opening valves XV-104, XV-142, PV-144 and XV-144 (shifted for clarity), showing how the invention allows for the calculation of precursor administered into reactor R-200 (distance between dashed lines), with programmable logic calculator XY-140 actively monitoring PI-144, TE-141. Absent the inventive Dosing Manifold, it would not be feasible to quantify the amount of precursor entering and being consumed within reactor R-200 over time. The combination of these elements provides for enhanced machine learning and the adoption of AI to optimize processing of ALD coated powders at the industrial scale.

FIG. 8: Pressure traces (top) corresponding to the process sequence (bottom) of opening valves XV-102, XV-122, PV-124 and XV-124 (shifted for clarity), showing how the invention allows for a process comprising alternating pressure swings due to dose pushing and purging from the vacuum, while independently enabling the calculation of precursor being recharged into The First Vaporization Vessel V-120 (distance between dashed lines), with programmable logic calculator XY-120 actively monitoring PI-124, TE-121. Absent the inventive Dosing Manifold, it would not be feasible to quantify the amount of precursor entering and being consumed within reactor R-200 over time. The combination of these elements provides for enhanced machine learning and the adoption of AI to optimize processing of ALD coated powders at the industrial scale.

FIG. 9: Lithos Reactor Isometric View

FIG. 10: Lithos Rotary Union/Reactor Cutaway with coaxial Process Rotary Union comprising SP-201 and SP-202

FIG. 11: One embodiment of the Filter Tree Section View and coaxial Process Rotary Union

FIG. 12: Filter tree end views for the embodiment of FIG. 11 showing different exemplary positions of outlet filters F-202a-c relative to F-201. Filter tree end views showing different positions of outlet filters F-202a-c revolving around rotating inlet filter F-201. Thick lines on each filter depict the surface area of each filter that is in the vertical direction at each exemplary position. Dashed boxes depict surface area regions restricting the direct line of sight between the top of R-200 and the shadowed filter surface area below.

FIG. 13: Lithos Reactor Interfacing

FIG. 14: PRU-200 Section View

FIG. 15: Alternative embodiment of inlet pipe/filter configuration to facilitate the processing of particulate substrates in a static gas phase, a continuous gas flow-through, or intermittent combinations thereof, where the inlet and outlet lines enhance gas-solids mixing during rotation.

FIG. 16: Foreline and Backpulse Vessel Subassembly PID

FIG. 17: Exhaust Stream Analysis and Process Quality Control PID

FIG. 18: Residual Gas Analyzer Manifold with pressure-modulated gas stream pathways, and Artificial Intelligence Module (AI-230)

FIG. 19: Pressure traces during a single sub-cycle comprising a sequence of precursor dose, static hold, dose push and soak.

FIG. 20: Mass spectrometry data (logarithmic scale) during three sub-cycles each comprising a sequence of precursor dose, static hold, dose push and soak, with analytical parameters “S” corresponding to product signal rise, and “t” corresponding to the time between product signal rise and precursor signal rise.

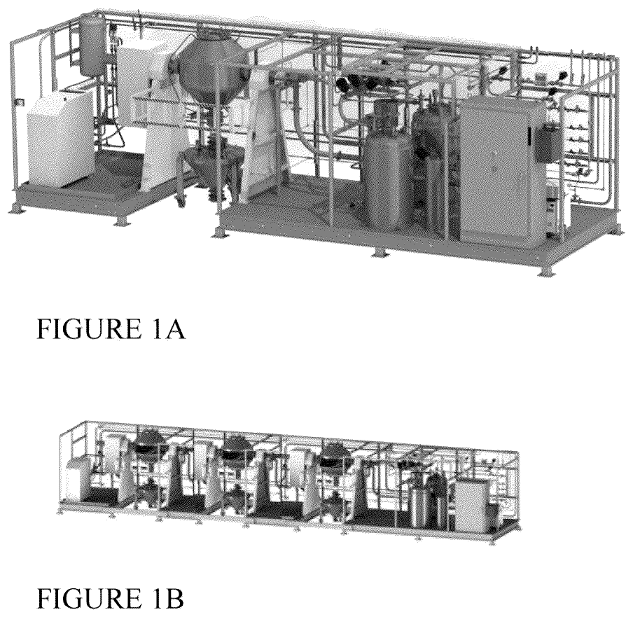

### APPARATUS AND SYSTEM SUBCOMPONENTS

This section describes the technical features, operation, and methods of the Lithos ALD system and subsystems, including:
Nitrogen Manifold
Reactive/Auxiliary Gas Inlet
ALD Precursor Manifold
Vaporization Tanks
Dosing Manifold
Reactor/Rotary Union
Foreline/Exhaust System
Multi-pressure Residual Gas Analyzer; and
Hot Oil Unit

### Nitrogen Manifold

Nitrogen can be used in many ways throughout the apparatus, but its main use is to purge sections of the skid of precursor. The Nitrogen manifold is comprised of branches that contain a pressure regulating valve, such that each branch is set to a different pressure using each pressure regulating valve based on its end application.

### Dosing Manifold

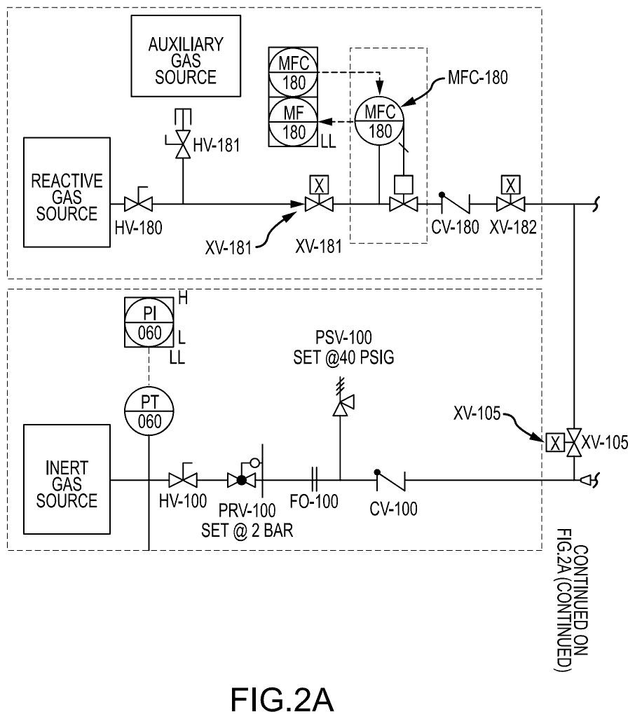

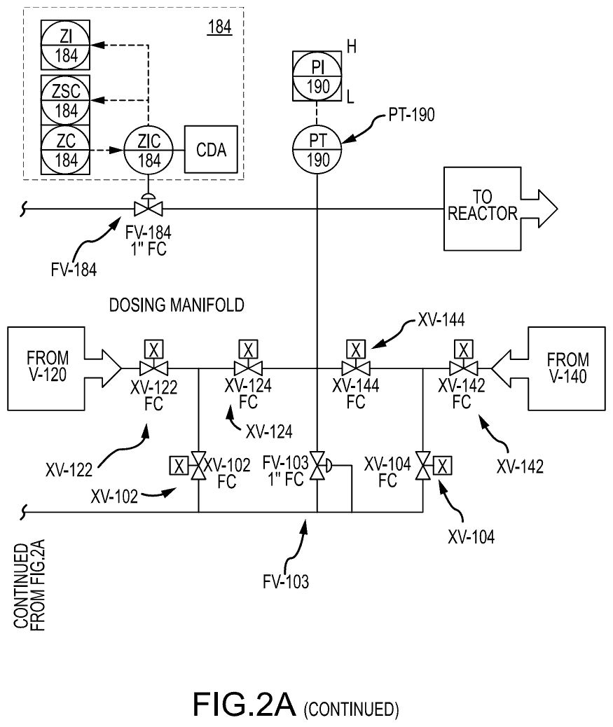

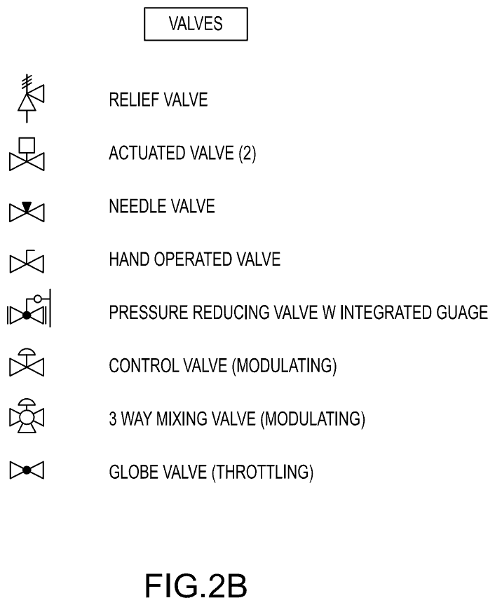

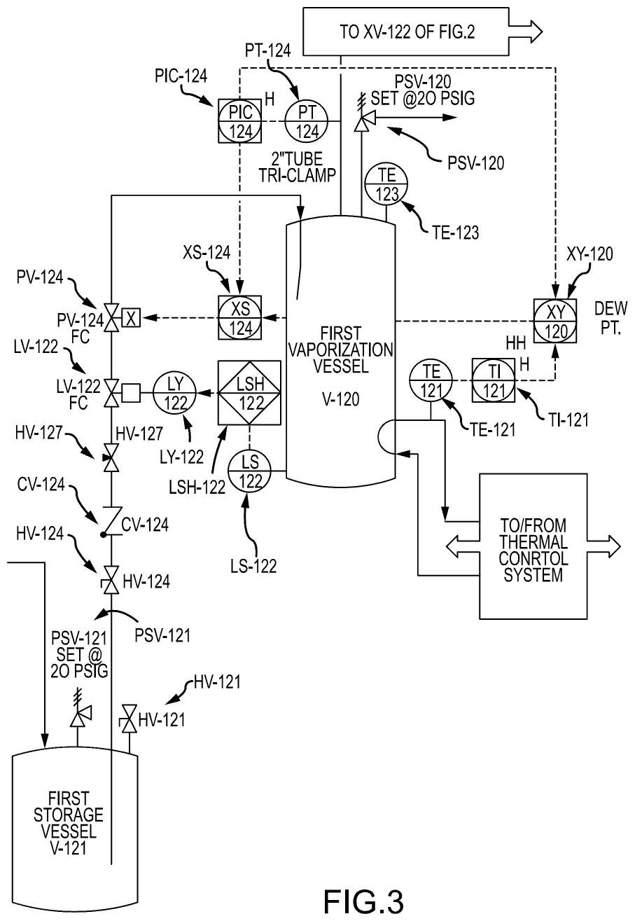

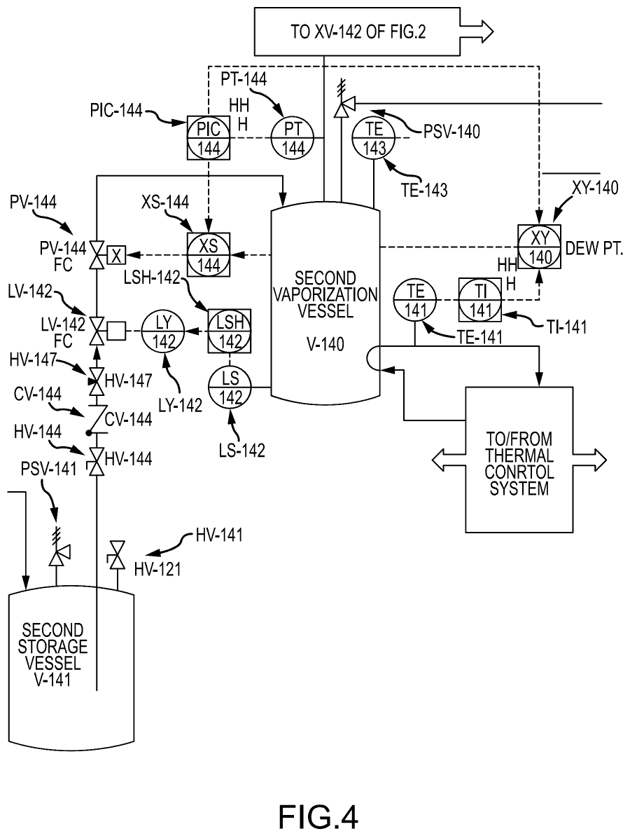

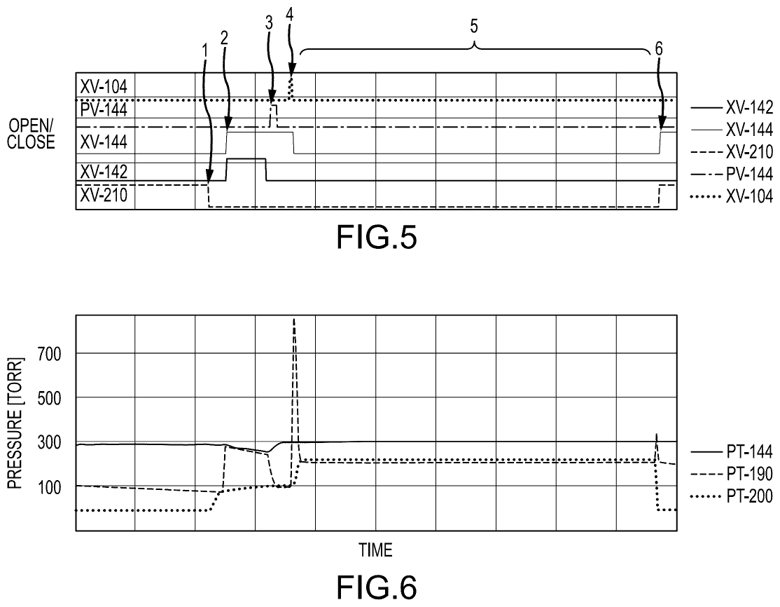

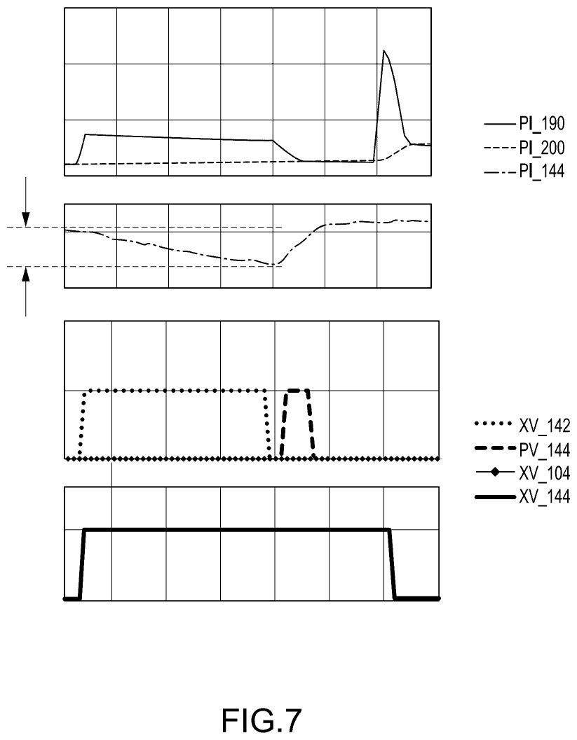

FIG. 2A shows an apparatus and system of the invention that serves as a Dosing Manifold of the invention. FIG. 2B provides the description for each category of valve shown in each piping and instrumentation diagram (PID). The dosing manifold is the only inlet to the reactor and controls when each precursor is introduced during the dosing step. The dosing manifold is plumbed from the inert gas source manifold, reactive gas (e.g. ammonia) or auxiliary gas (e.g. dilute O₂) inlet, both vaporization tanks, and is plumbed to the reactor. As depicted, computer-controlled valve XV-122 is in fluid communication with vaporization vessel V-120 of FIG. 3, and its operating pressure is known from pressure transducer PT-124 of FIG. 3. Similarly, computer-controlled valve XV-142 is in fluid communication with V-140 of FIG. 4, and its operating pressure is known from pressure transducer PT-144 of FIG. 4. The Dosing Manifold comprises a series of volume elements that are specific to each precursor that is delivered to R-200 from V-120 or V-140 (or additional precursors from an analogous apparatus and system (e.g. a V-160, a V-180, etc., having an identical layout and approach as V-120 and V-140, not shown).

Volume Element 12X (VE-12X) is defined as the pipe volume contained between XV-122, computer-controlled valve (XV-124) and computer-controlled valve (XV-102). Similarly, Volume Element 14X (VE-14X) is defined as the pipe volume contained between XV-142, computer-controlled valve (XV-144) and computer-controlled valve (XV-104). As such, an object of the invention of VE-12X and VE-14X is a means of delivering: i) a controlled amount of vapor phase precursor of V-120 to R-200 based upon VE-12X and PT-124 and the appropriate thermodynamic equation specific to the vapor phase precursor of V-120; and ii) a controlled amount of vapor phase precursor of V-140 to R-200 based upon VE-14X and PT-144 and the appropriate thermodynamic equation specific to the vapor phase precursor of V-140. For example, the Antoine Equation with appropriate constants can be used for trimethylaluminum (TMA). In such an example, during a TMA dose, valves XV-142 and XV-144 will open to let vaporized TMA move to the reactor and during a water dose, valves XV-122 and XV-124 will open to let water vapor move to the reactor. Valves XV-102, XV-104 and FV-103 are plumbed to the nitrogen manifold and are used during a dose push or when purging sections of the dosing manifold of precursor. Valves FV-103 and FV-184 are flow regulating valves. These valves provide visual feedback to the user through an LED indicator located at the top of the valve. States are as follows:

$$Red = Closed$$

$$Orange = Open < 100 \%$$

$$Green = Completely Open$$

An object of the Dosing Manifold is to prohibit the interaction of any reactive gas species deployed in the system. As such, only inert gas is intended to pass through a control valve XV-105, XV-102, XV-104, and a modulating control valve (FV-103) to prevent cross-contamination of reactive gas species.

### Vaporization Vessels

FIG. 3 shows an apparatus and system comprising a First Vaporization Vessel (V-120) and a First Storage Vessel (V-121), a series of five valves, which when all are operatively in an open position, provides fluid communication between V-121 and V-120, and a Thermal Control System having a means of providing heat to V-120.

The first storage vessel V-121 comprises:
an inlet,
a first outlet having a pressure relief valve with a set point (PSV-121) that remains in the closed position while the pressure of V-121 is below the set point of PSV-121,
a second outlet having a dip tube that extends inward into V-121 approaching the bottom of V-121,
and optionally an additional port capable of functioning as an inlet or an outlet and isolated by manual valve (HV-121).

The first vaporization vessel V-120 comprises:
a first inlet having a dip tube that extends inward into V-120,
a first outlet in fluid communication with a Dosing Manifold,
a second outlet having a pressure relief valve with a set point (PSV-120) that remains in the closed position while the pressure of V-120 is below the set point of PSV-120, and
a temperature sensor (TE-123) that measures the internal temperature of V-120.

The thermal control system having a means of providing heat to V-120, comprising a temperature sensor (TE-121) in electrical signal communication with a temperature indicator (TI-121) and a programmable logic calculator (XY-120).

The five valves of the second outlet of V-121 comprising:
1. a manual valve (HV-124) capable of being configured in an open or closed position by hand;
2. a computer-controlled valve (CV-124) capable of being configured in an open or closed position by computer control;
3. a manual needle valve (HV-127) capable of being modulated between an open or closed position by hand, and able to regulate the flow through HV-127 when all five valves are operatively in an open position and can vary the pressure within V-120 by increments of 0.1 Torr or lower;
4. a first pneumatic valve (LV-122) in fluid communication with the first inlet of V-120 capable of being configured in an open or closed position from level relay (LY-122) that may provide clean, dry air (CDA) or similar at sufficient pressure to the actuation mechanism of LV-122, and in electrical signal communication with programmable level switch (LSH-122) and a level sensor (LS-122) capable of measuring the level of liquid, if any, within V-120; and
5. a second pneumatic valve (PV-124) in fluid communication with the first inlet of V-120 and in electrical signal communication with a switch (XS-124), wherein XS-124 is in electrical signal communication with a pressure indication controller (PIC-124) and XY-120, and wherein PIC-124 is in electrical signal communication with a pressure transducer (PT-124) located at the outlet of V-120.

FIG. 4 shows an apparatus and system comprising a Second Vaporization Vessel (V-140) and a Second Storage Vessel (V-141), a series of five valves, which when all are operatively in an open position, provides fluid communication between V-141 and V-140, and a Thermal Control System having a means of providing heat to V-140.

The second storage vessel V-141 comprises:
an inlet,
a first outlet having a pressure relief valve with a set point (PSV-141) that remains in the closed position while the pressure of V-141 is below the set point of PSV-141,
a second outlet having a dip tube that extends inward into V-141 approaching the bottom of V-141,
and optionally an additional port capable of functioning as an inlet or an outlet and isolated by manual valve (HV-141).

The second vaporization vessel V-140 comprises:
a first inlet having a dip tube that extends inward into V-140,
a first outlet in fluid communication with a Dosing Manifold,
a second outlet having a pressure relief valve with a set point (PSV-140) that remains in the closed position while the pressure of V-140 is below the set point of PSV-140,
a temperature sensor (TE-143) that measures the internal temperature of V-140 and is in electrical signal communication with a temperature indicator (TI-143)

The thermal control system having a means of providing heat to V-140, comprising a temperature sensor (TE-141) in electrical signal communication with a temperature indicator (TI-141) and a programmable logic calculator (XY-140).

The five valves of the second outlet of V-141 comprising:
1. a manual valve (HV-144) capable of being configured in an open or closed position by hand;
2. a computer-controlled valve (CV-144) capable of being configured in an open or closed position by computer control;
3. a manual needle valve (HV-147) capable of being modulated between an open or closed position by hand, and able to regulate the flow through HV-147 when all five valves are operatively in an open position and can vary the pressure within V-140 by increments of 0.1 Torr or lower;
4. a first pneumatic valve (LV-142) in fluid communication with the first inlet of V-140 capable of being configured in an open or closed position from level relay (LY-142) that may provide clean, dry air (CDA) or similar at sufficient pressure to the actuation mechanism of LV-142, and in electrical signal communication with programmable level switch (LSH-142) and a level sensor (LS-142) capable of measuring the level of liquid, if any, within V-140; and
5. a second pneumatic valve (PV-144) in fluid communication with the first inlet of V-140 and in electrical signal communication with a switch (XS-144), wherein XS-144 is in electrical signal communication with a pressure indication controller (PIC-144) and XY-140, and wherein PIC-144 is in electrical signal communication with a pressure transducer (PT-144) located at the outlet of V-140.

A further description of the vaporization vessels used for vaporizing the precursor in the example of TMA or DEZ delivery. The TMA or DEZ precursor enters the TMA/DEZ vaporization vessel from the TMA/DEZ manifold whereas the water precursor enters the water vaporization vessel from the water source tank. Both precursors are vaporized by heating the tanks to their respective operating temperature using the thermal control system for each vaporization vessel.

During an Al₂O₃ ALD coating process using TMA and H₂O, valves LV-142 and PV-144 will open to charge TMA to V-140 from V-141 whereas LV-122 and PV-122 will open to charge water to V-120 from V-121. Valves HV-127 and HV-147 are flow control valves. It is important for the precursors to be in the vapor state. This is monitored by the pressure and temperature and XY-120 and XY-140. Pressure and temperature are monitored by PT-124, TE-123 and PT-144, TE-143 for water and TMA respectively.

In the event of an over pressurization, there are pressure safety valves located on each tank (PSV-120 and PSV-140) that will send the precursors to a safe location away from the apparatus. The outlet of PSV-140 may be purged with low pressure nitrogen to keep air away from the PSV-140 seal.

Each vaporization vessel is equipped with a level sensor to detect the presence of liquid precursor, as a safeguard to ensure that the precursors are vaporizing and not condensing inside the vaporization vessel. The level of each precursor is also actively monitored while charging the vaporization vessels to ensure vaporization is occurring. If either level sensor detects liquid water or TMA in either vaporization vessel as measured by LS-122 or LS-142, respectively, LV-122 or LS-142 will close to prevent more precursor from reaching the respective vaporization vessel, and the Thermal Control System (e.g. a hot oil unit) for that vaporization vessel will shut off. The TMA vaporization vessel preferably only contains TMA vapor and not liquid TMA as this can present an overpressure hazard for the TMA vaporization vessel and reactor if combined with other abnormal operating conditions.

### Reactor/Rotary Union

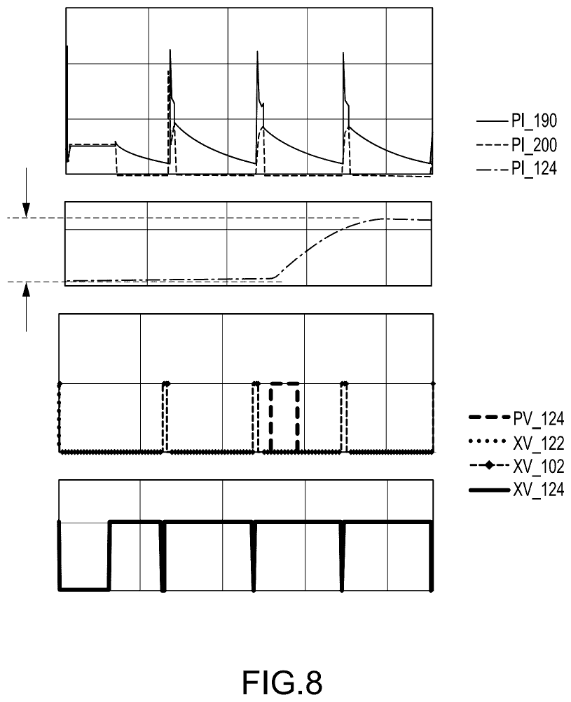

The reactor shown in FIG. 9 is a rotary blender with a maximum capacity of 7.5 ft³ (~212L), however larger or smaller vessels are able to be utilized. Specifically, vessel sizes of 25L, 50L, 100L, 200L, 250L, 350L, 600L, 800L, 1250L and 1600L have been deployed with appropriate scaling of the structural frame and the inlets and outlets. This is the main vessel that houses the material to be coated. The material is inserted into the vessel through the gate valve (HV-200) located on the bottom of the reactor when looking at it in the orientation below. Material is mixed by rotating the reactor which causes the material to fall or cascade when it approaches or reaches the top of the rotation, assisted by the angle of the sidewalls and optional internal baffles. This process happens throughout the entire recipe to ensure evenly coating all material. The rotational speed of the vessel can be chosen by the user through the HMI. The reactor is rotated horizontally at a controllable frequency ranging from 0.5 to 30 revolutions per minute, and along the same axis as the coaxial gas inlet and gas outlet, and wherein the coaxial gas inlet and gas outlet rotate with the reactor.

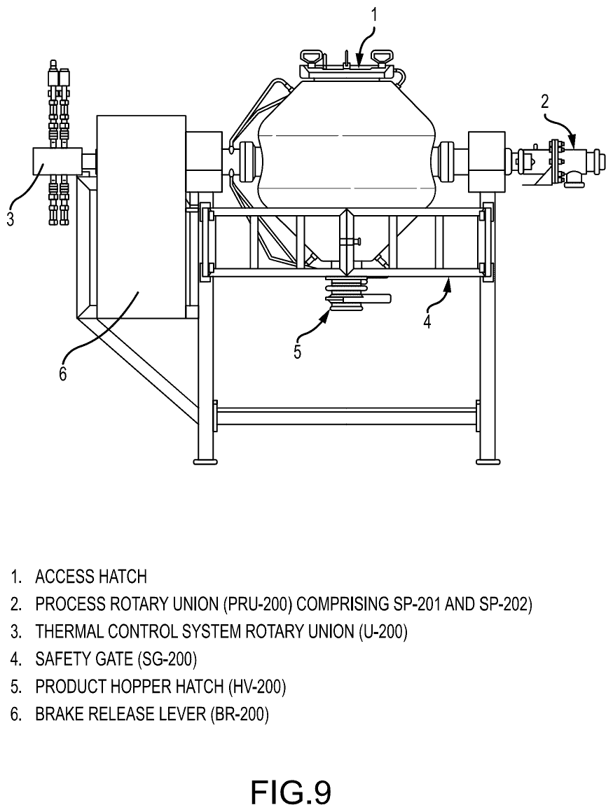

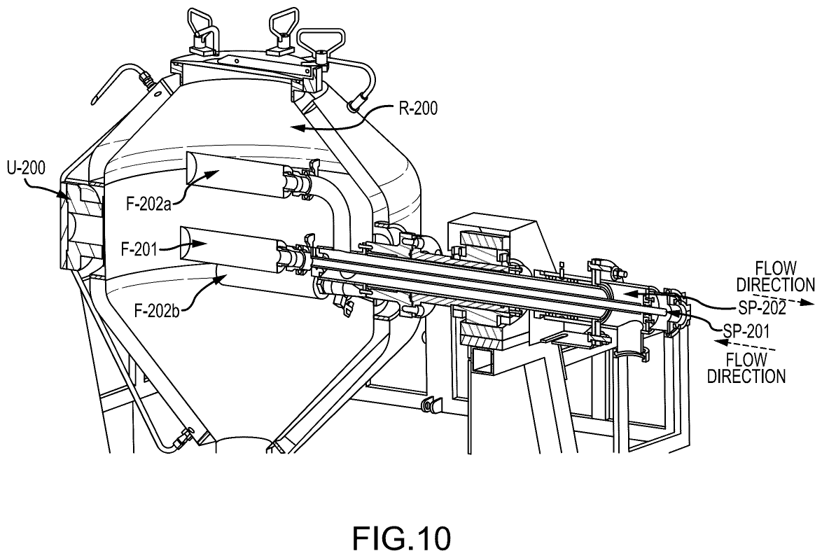

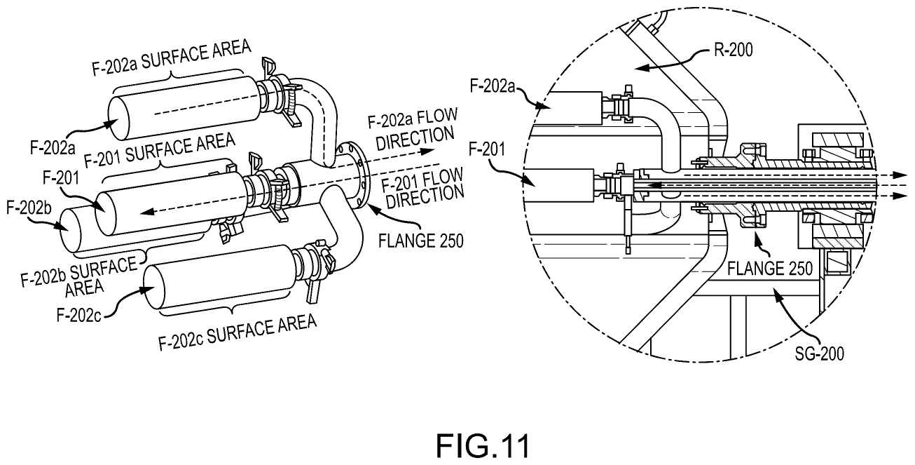

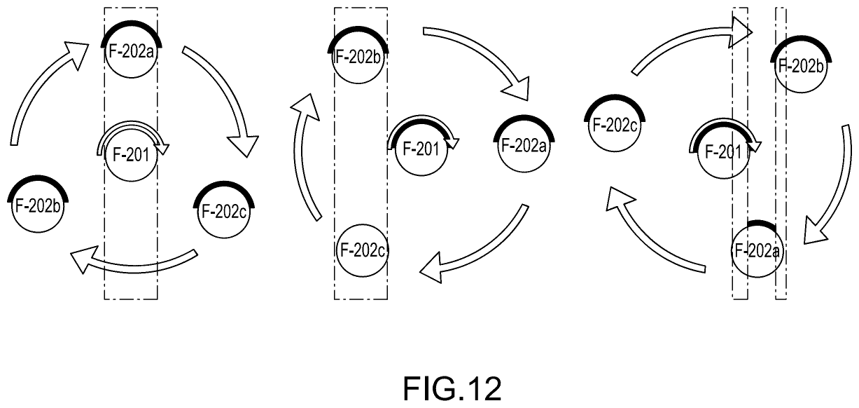

Inside the reactor a filter tree is used to convey gases in and out of the reactor. In one embodiment, the filter tree contains four (preferably porous stainless steel) filters. The center filter (F-201) is the dosing filter where the precursor is introduced into the reactor. The outer 3 filters (F-202a, F-202b and F-202c) are used to evacuate residual precursors and reaction products from the reactor. The vacuum pump will pull these gases through these three filters to the foreline/exhaust assembly which will then dispose of the gases as desired. The filter tree is secured to the inside face of the vessel with a flange connection so when the vessel rotates, the F-201 rotates with it, and F-202a, F-202b and F-202c revolve around F-201. See FIGS. 10-12.

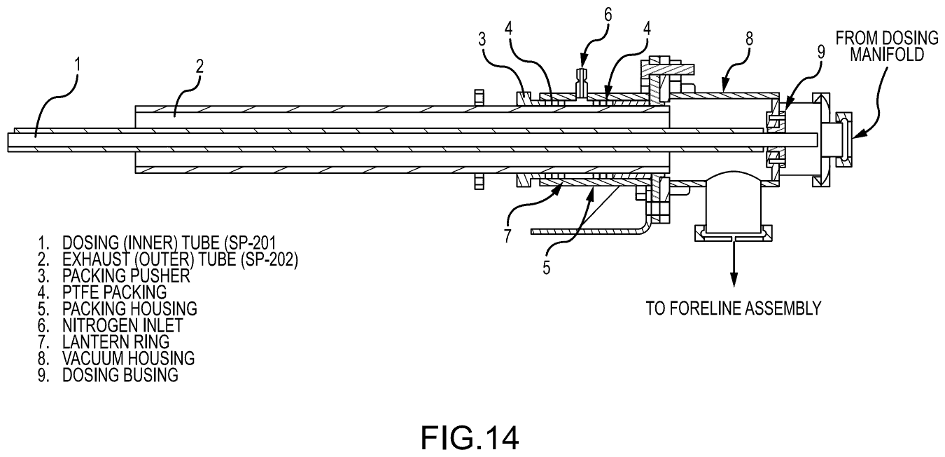

In another embodiment, the filter tree comprises at least two evenly spaced inlet filters that are positioned within 10-20% of the vessel radius away from the wall of the vessel, such that the inlet filters administer gases simultaneously within the powder bed, from the filters that are rotated into a lower position, and above the powder bed, from the filters that are rotated in an upper position. In this embodiment, the outlet filter may be one or more, centralized filters, or be similarly positioned within 10-20% of the vessel radius away from the wall of the vessel, evenly spaced between the inlet filters. In this embodiment, the system may be operated using a static dose process, a continuous flow-through process, or an intermittent combination of both. The selection of the distance away from the wall of the vessel is based on the bed height (i.e. the fill fraction of the reactor vessel), where the horizontal plane of any inlet filter at its widest point and at its bottom-most position is 20-80% of the depth of the bed when the reactor is not rotating. See FIG. 15.

In another embodiment, the filter tree comprises at least two evenly spaced [from a centralized filter] inlet pipes comprising gas jets, where the inlet pipes are positioned within 10-20% of the vessel radius away from the wall of the vessel, such that the inlet pipes administer gases simultaneously within the powder bed, from the jets of the inlet pipe when rotated into a lower position, and above the powder bed, from the jets of the inlet pipe when rotated in an upper position. The jets are preferably pointed in a direction opposite the rotation of the reactor so as not to uptake powder into the jets when no gas is flowing. In this embodiment, the outlet filter may be a single, centralized filter, or be similarly positioned within 10-20% of the vessel radius away from the wall of the vessel, evenly spaced between the inlet pipes. In this embodiment, the system may be operated using a static dose process, a continuous flow-through process, or an intermittent combination of both. The selection of the distance away from the wall of the vessel is based on the bed height (i.e. the fill fraction of the reactor vessel), where the horizontal plane of any inlet pipe at its widest point and at its bottom-most position is 20-80% of the depth of the bed when the reactor is not rotating.

The selection of jetted pipes versus filters for the gas inlets may be based on particular properties of the powders (e.g. sub-micron particles that tend to agglomerate during processing), or may be based on the specific reactive precursors used in the ALD process. For example, the use of ozone (or other radical-enabled chemistry) is impractical with porous stainless steel filters due to the deactivation or recombination of radical-bearing species prior to entering the reactor. In this embodiment, jetted pipes are designed to minimize the loss of flux of the active species prior to reaching the intended powder surface to carry out the intended ALD process.

In the case of porous filters, the specific number of filters is not as critical as is the ability to ensure that the entire surface area of each outlet filter F-202a-c can be downward-facing at some rotational angle of R-200. This feature, when coupled with the programmable backpulse function ensures minimal product is built up and retained on the outlet filters during the process and reduces the likelihood fine particles can be entrained and pushed through the filters and into the foreline/exhaust section of the apparatus.

There are two inlets on each side of the reactor which bring in different fluids. Rotary unions are used as the interfacing connection to and from the reactor. The Process Rotary Union (PRU-200) is comprised of coaxial tubes SP-201 and SP-202. Precursors are introduced from the Dosing Manifold, to SP-201, through F-201 and into R-200. Reaction products are removed from R-200 simultaneously through F-202a, F-202b and F-202c, to SP-202, and on to the Exhaust Manifold. PRU-200 is made up of custom manufactured parts which use o-rings and packing to separate the precursor inlet and outlet, and keep all precursors and byproducts contained within the closed system.

The dosing occurs through the dosing tube SP-201 within the union which is isolated from the vacuum side of the rotary union with the dosing bushing on the outside of the reactor and a dynamic o-ring, located a few inches from the dose inlet flange. SP-201 is typically secured to the filter tree (e.g., via a set screw), so SP-201 rotates synchronously with R-200 and F-201. In some embodiments, SP-201 is not secured to the filter tree, such that the filter (or jetted pipe) tree does not rotate synchronously with R-200. This configuration is particularly beneficial for asymmetric filter trees, where an inlet filter or jetted pipe predominantly resides in the lower region of the reactor, and the powder is continually cascading onto the top of the inlet filter(s) or jetted pipe(s) that predominantly reside in the lower region of the reactor.

In at least one embodiment, the Process Rotary Union (PRU-200) is comprised of three coaxial tubes SP-201a, SP-201b, and SP-202. Similar to the base embodiment, one class of precursor (such as high vapor pressure precursors including TMA, DEZ and water) is introduced from the Dosing Manifold, to SP-201a, through F-201a and into R-200. A different class of precursor (low vapor pressure precursors, precursors sublimed from solid sources, ozone, plasma or other precursors requiring special handling needs, is introduced from the Dosing Manifold, to SP-201b, through F-201b and into R-200. Not only does this provide a spatial separation of dissimilar precursor classes, this also allows the user to incorporate a combination of inlet filters for high vapor pressure precursors (e.g. F-201a) and jetted pipes for precursors requiring special handling such as ozone through F-201b. Reaction products are removed from R-200 simultaneously through F-202a, F-202b and F-202c, to SP-202, and on to the Exhaust Manifold.

The removal of residual precursor and reaction products through F-202a, F-202b and F-202c occurs through the outer tube SP-202 which surrounds the dosing tube SP-201. The outer tube is connected to the outside face of the R-200 with a flange connection, so SP-202 rotates synchronously with R-200. As such, F-202a, F-202b and F-202c revolve synchronously with the rotation of R-200, F-201, SP-201 and SP-202.

SP-202 is isolated from atmosphere using the packing housing. This housing contains PTFE packing which is forced against the sealing surface of the outer tube and packing housing using the packing pusher. The packing is constantly being purged with low pressure nitrogen through the lantern ring as a secondary safeguard to mitigate any possibility for fluid communication between the reactor and the atmosphere.

The packing housing is mounted with a flange connection to the vacuum housing. The vacuum housing contains the inlet and outlet connections from the dosing manifold and to the vacuum pump. These two housings are mounted to a bracket that is secured to the frame so neither the packing housing, nor the vacuum housing move while R-200 rotates.

The other rotary union, U-200, is where the hot oil is circulated from the hot oil unit to the jacket of the reactor. Hot oil is circulated through the jacket to maintain the desired temperature of the reactor. This rotary union works similarly to the other, however is much less complex. Each port is isolated from each other and atmosphere by two o-rings that are chemically and thermally compatible with the precursors and operating temperatures, typically Viton, Kalrez or similar known/compatible materials for o-rings.

Located at the top of the reactor is an access hatch which is used for servicing the reactor and the filter tree inside. Located at the bottom of the reactor is a manually actuated gate valve. This valve is used for material loading/unloading and should only be used when doing so. Valve opens by turning the manual actuator clockwise to close and counterclockwise to open. There is an open/close indicator located on the front of the valve to show the state. The reactor is surrounded by two sets of safety gates which when secured to one and other, allow the reactor to rotate via a proximity switch. If the gates are not secured, the reactor will not be able to rotate via software. If the user wishes to rotate the reactor manually, there is a lever located on the front of the reactor on the left side, that when pulled, will release the brake on the blender and allow the user to rotate the vessel.

### Foreline (Vacuum and Filtration)

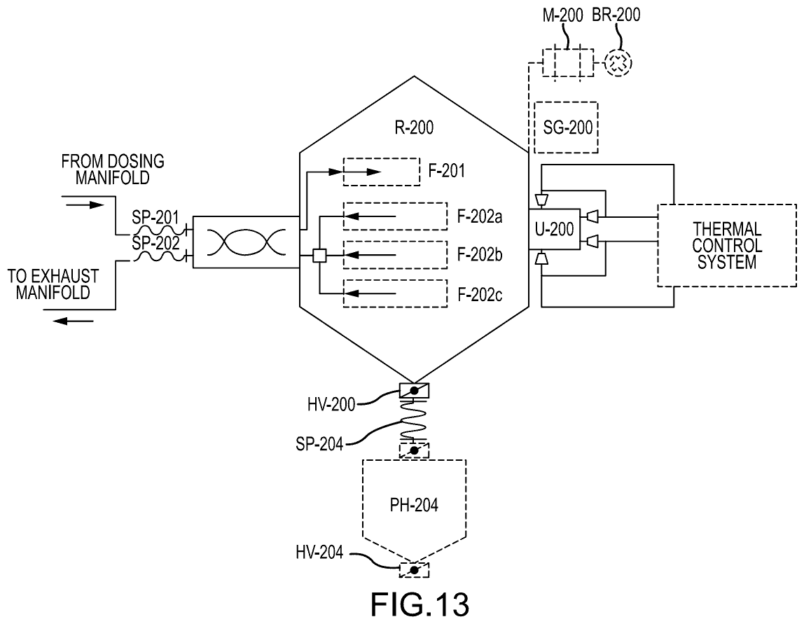

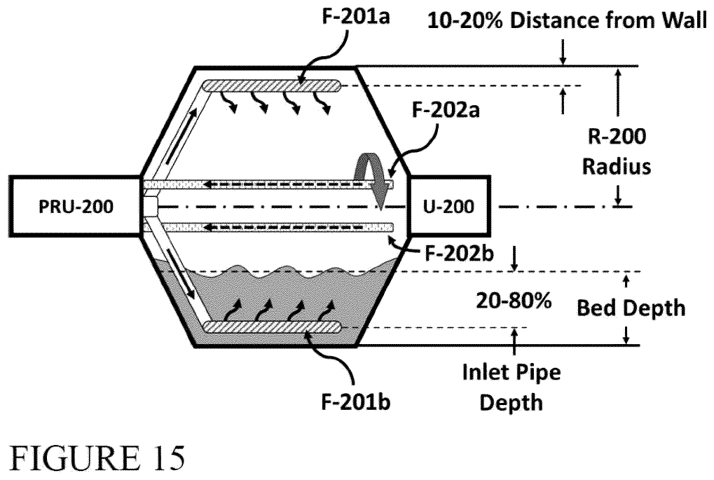

The foreline assembly is used to convey the reaction products, residual precursors, and inert gases out of the Lithos system. See FIGS. 14b-18. There are three possible routes for the exhaust from the reactor: to a passive abatement system and through the vacuum pump, to an active abatement system designed to capture residual precursors for reuse and through the vacuum pump, or to the RGA for analysis of the composition of the exhaust gas. The outlet of the vacuum pump may be further equipped with a scrubber, burn box or similar device known in the art to destroy/remove any unwanted species in the final exhaust gas.

The vacuum pump is the main component for removing ALD reaction products from the system. PV-210 is an automatic modulating globe valve that is used to control the flow to the pump. The pump is protected by a filter upstream that will capture any residual particles that pass through the reactor filters. This filter status is monitored with a pressure transducer up, PT-210, and downstream, PT-212, of it by taking the differential between the two. The differential pressure can be utilized to determine when the filter needs to be changed.

The Foreline assembly also contains the backpulse vessel V-205 which is used to remove material from the reactor filters. The backpulse vessel is filled with nitrogen or other inert process gas and when needed, XV-210 is closed and a pulse of nitrogen by opening XV-205 is sent through the outlet filter(s) in the reactor. This burst of positive pressure will remove powder that is situated on the outlet filter(s).

During a reactive gas dosing cycle (e.g. ammonia or ozone), the reactive gas recycle branch will be used to direct the leftover reactive gas to the abatement system. PV-201 is also an automatic modulating globe valve that is used to control the flow to the abatement system, or a specific abatement system if more than one is deployed. The foreline assembly contains a pressure sensor, PT-200, upstream of the flow regulating valve which is used to monitor pressure during processing. Heat trace and insulation are utilized throughout the foreline assembly to prevent the condensation of any residual precursors or byproducts.

### RGA Sampling

The apparatus includes a mass spectrometer (A-230) to assist in timing doses during chemistry operations as well as leak checking. The mass spectrometer is comprised of a Residual Gas Analyzer (RGA) and a turbo pumping station.

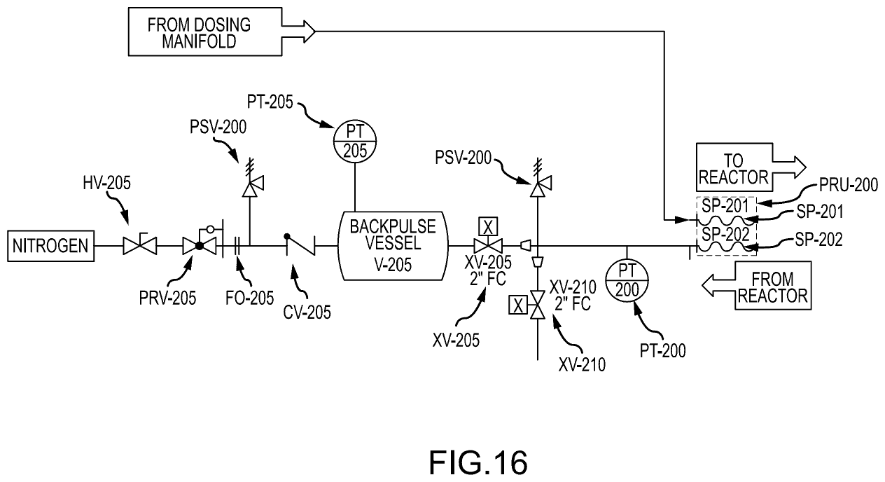

The system is preferably operated with the assistance of the mass spectrometer to monitor chemistry, determine when a reaction is complete, and avoid overdosing precursor. The inlets to the mass spectrometer are located at the outlet of the reactor off the vacuum foreline. It is important that orifices be selected such that the pressure at the RGA is in the range of ~10⁻⁶-10⁻⁵ Torr during sampling. Significantly lower pressures will result in a poor signal-to-noise ratio, pressures above 10⁻⁵ Torr lead to a non-linear signal response, and pressures above 10⁻⁴ Torr can damage the RGA filament and pumping station. To provide more operating flexibility, the apparatus may comprise at least two sample ports, one for high-pressure sampling and one for low-pressure sampling as shown in FIG. 17.

High-pressure sampling is performed upstream of PV-210 via the sample inlet valve XV-230. It should be used when the reactor pressure is high, in the range of 1000 to 1500 Torr. The small, 4-μm orifice on the process side of XV-230 drops the sample pressure and restricts flow to the RGA pumping station. A second, larger orifice on the RGA side of XV-230 protects the RGA and pumping station from a transient pressure pulse when XV-230 first opens. Due to the extremely low flow rates, there is an unavoidable sample delay for high-pressure sampling. It is therefore most suitable for monitoring long process steps under steady state conditions over many minutes to hours.

Low-pressure sampling is performed downstream of PV-210 via the sample inlet valve XV-232. It has a fast response time and is intended only for sampling at pressures below 10 Torr. If the foreline pressure measured by PT-210 exceeds 10 torr, XV-232 will automatically close to protect the RGA and pumping station. The faster response time of the low-pressure sampling port makes it more useful for leak checking or quantifying reaction byproducts. When leak checking, the system should be under active vacuum with PV-210 fully open so that the RGA can quickly detect any helium or argon gas entering from a leak. When monitoring reaction byproducts, the best time to sample is during the evacuation step at the end of each precursor sub-dose. To get a consistent, comparable, and steady signal, consider setting PIC-210 to a value in the range of 0.5-1 Torr. This will slow the evacuation of the reactor and maintain a steady pressure in the foreline downstream of PV-210 for long enough to get a repeatable sample that can be compared from sub-dose to sub-dose.

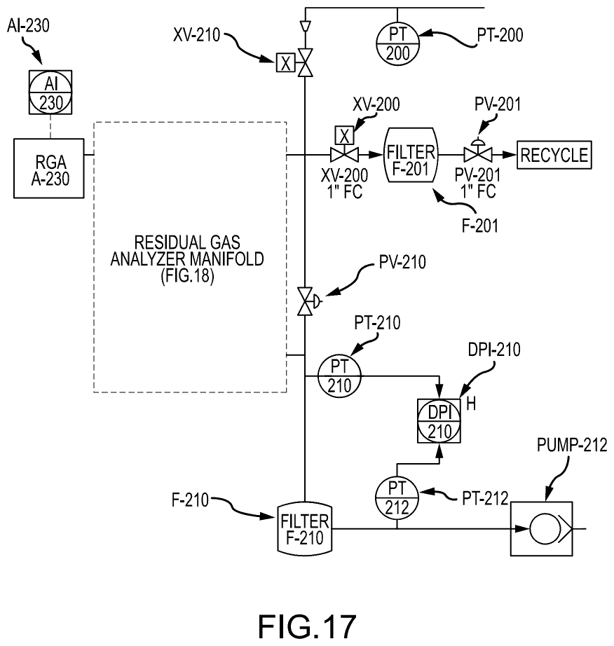

FIG. 18 depicts a schematic of a multi-pressure RGA system. XV-230 and XV-232 function similarly to how they are described in FIG. 17, and in each branch the size of each filter gasket may increase from right (foreline side) to left (RGA side) to follow the pressure reduction feature described previously. For example, for less than 10 Torr pressure monitoring, XV-232 may only be used and J=50. For 10-100 Torr pressure monitoring, XV-230 may be used with I=10 and H=40.

Another object of this invention is the multi-pressure RGA sampling apparatus of FIG. 18, which may be used with the rotary batch (or semi-batch) apparatus and system described herein, or in a semi-continuous system, a fully continuous fluidized bed reactor system, or a fully continuous moving bed reactor system. With each of these systems, the pressure and pressure swing characteristics require adapting the configuration of the orifice sizes within each valved leg to the desired flow rates and residence times of particular process steps.

### ALD Processing Advantages

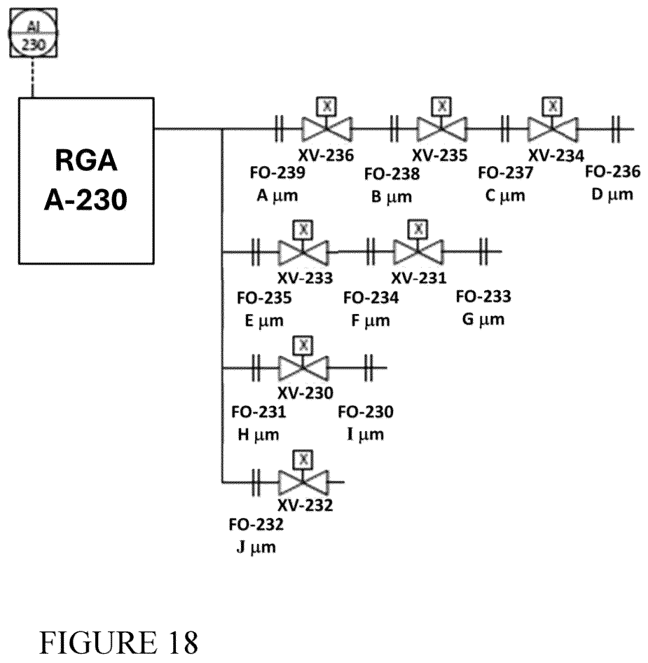

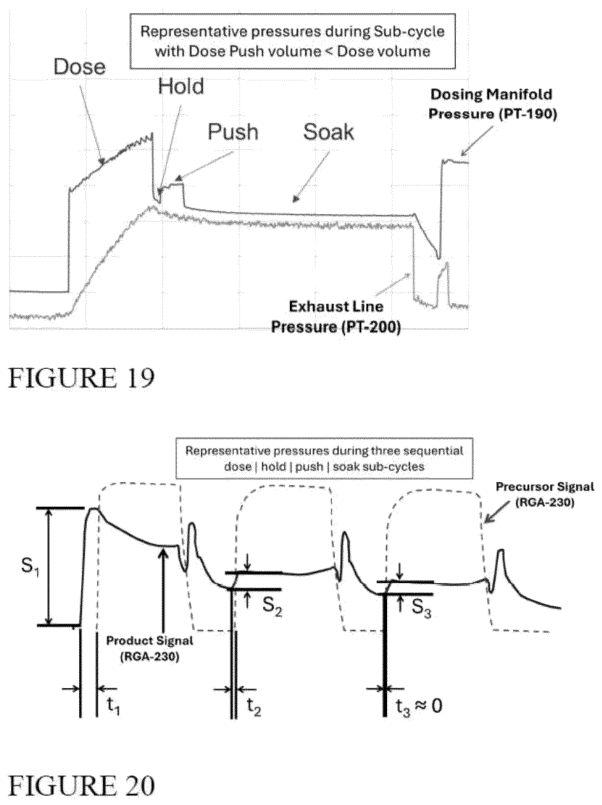

A sub-cycle dosing method in accordance with one embodiment of the invention is shown in FIGS. 19-20. The prior art teaches that ALD at the laboratory scale is performed using a dose|purge|dose|purge approach, however once ALD processes are scaled to prototype, pilot or industrial scales, new dosing approaches and analytical techniques are required to increase performance and decrease operating costs. The Lithos system allows for independent dose, dose hold, dose push and soak steps that are enabled by the Dosing Manifold of FIG. 2A. When combined with RGA-230, two operating regimes have been discovered that have yielded unexpected results.

In one embodiment, the inventive ALD system allows for a pressure step-up within dosing cycles, wherein each consecutive sub-cycle steps up the pressure within the reactor by at least 50 Torr. This has been found to increase the reaction performance over time, leading to reduced precursor usage and higher throughput than using conventional processes of the prior art. In this embodiment, the method comprises administering a known quantity and total surface area of powder to a reactor of an ALD system comprising a dosing source, a reactor and a vacuum pump, a first controllable valve interposed between the dosing source and the reactor; and a second controllable valve interposed between the reactor and the vacuum pump; and bringing the reactor to the appropriate reactor temperature and reactor pressure (level of vacuum); Carrying out a first sub-cycle comprising:
i) administering from a dosing source, a first precursor dose into the reactor at a first controlled precursor temperature for a first time period;
ii) terminating the first precursor dose and isolating the reactor from the dosing source and vacuum pump, and applying a first static hold for a second time period;
iii) administering a first dose push comprising inert gas into the reactor at an inert gas pressure that is at least 100 Torr higher than the first precursor at the first controlled precursor temperature, for a third time period;
iv) terminating the first dose push and isolating the reactor from the dosing source and vacuum, and applying a second static hold for a fourth time period; and
   repeating the sub-cycle N times by repeating steps (i) through (iv), wherein the pressure of the reactor during the fourth time period of each sub-cycle is at least 50 Torr greater than the pressure of the reactor during the fourth time period of each immediately preceding sub-cycle.

In another embodiment, the inventive ALD system provides a systematic means of controlling the dose, hold, dose push and soak times using a combination of RGA signal data and pressure level monitoring, or alternatively developing a diagnostic test that can be intermittently applied to monitor the health of the ALD system and the coated product during processing. In this embodiment, the method comprises administering a known quantity and total surface area of powder to a reactor of an ALD system comprising a dosing source, a reactor, a residual gas analyzer (RGA), a vacuum pump, a first controllable valve interposed between the dosing source and the reactor; and a second controllable valve interposed between the reactor and the vacuum pump, and the RGA operatively connected to the reactor; and bringing the reactor to the appropriate reactor temperature and reactor pressure (level of vacuum); Carrying out an Nth sub-cycle comprising:
i) administering from a dosing source, a first precursor dose into the reactor at a first controlled precursor temperature for a first time period and independently monitoring the RGA signals of the ALD reaction product and the precursor, wherein the maximum height of the RGA signal of the ALD reaction product is defined as S_{N} and the first time period is defined as tu, the time between the initial rise of the RGA signal of the ALD reaction product and the initial rise of the RGA signal of the precursor;
ii) terminating the first precursor dose and isolating the reactor from the dosing source and vacuum pump, and applying a first static hold for a second time period;
iii) administering a first dose push comprising inert gas into the reactor at an inert gas pressure that is less than that of the first precursor at the first controlled precursor temperature, for a third time period;
iv) terminating the first dose push and isolating the reactor from the dosing source and vacuum, and applying a second static hold for a fourth time period; and
repeating the sub-cycle of steps (i) through (iv) at least two times, and until the product of S_{N}·t_{N} during the Nth sub-cycle is ≤5% of the product of S₁·t_{1·}

All of the embodiments described herein are non-limiting and are intended to illustrate structure and operation of the inventive apparatus, system and method. In the non-limiting embodiment in which the thermal fluid can be shared amongst the apparatus and system of V-120, V-140 and R-200, the thermal control system allows for each connected and apparatus to operate at the same operating temperature. A thermal control system may be common to V-120 and V-140, and a separate thermal control system may be used for R-200. Alternatively, only one of V-120 or V-140 may employ a thermal control system common to R-200, with the other of V-120 or V-140 employing a separate thermal control system. Each apparatus or system may employ a dedicated thermal control system for each apparatus or system. In some embodiments an electrical heating system may be deployed, where the thermal fluid valves may be replaced by electrical circuits (e.g. electrical heat trace lines) operating in series or parallel, and individually controlled using means and techniques known to one of ordinary skill in the art.

### Operation

### Loading Substrate

The Lithos tool is designed to mate with a portable material transfer vessel to charge powder. Because the Lithos reactor volume may be more than 10 times that of any portable material transfer vessel, the loading operation may be repeated multiple times to fill the system. As processes scale, it becomes preferable to load from a single, large hopper supported by an overhead gantry or via a pneumatic transport system, or similar industrial powder handling solution; especially when deploying a semi-batch/semi-continuous embodiment. The following guidelines can be used as a starting point for loading air-sensitive material into the reactor using the portable material transfer vessel.

Ensure the system is ready to accept uncoated substrate:
1. System is empty
2. Reactor is positioned with the load port at very top of rotation and rotation is stopped
3. Appropriate safeguards taken for entering the rotating reactor zone such as LOTO or other requirements
4. No automated recipe is running (manual controls).
5. Reactor is ready to receive substrate
6. Atmosphere inside reactor is inert gas
7. Pressure inside reactor is atmospheric
8. Reactor is not hot
9. Reactor filters are all installed

Load Substrate into reactor:
1. Open the reactor safety gate
2. Position mobile stairs in front of the reactor and ensure that the staircase is locked in place
3. Open HV-200 to equalize pressure across the cap on HV-200, then close HV-200
4. Pump down the reactor and refill with nitrogen to atmospheric pressure to remove any oxygen that entered the system from opening HV-200.
5. Remove the 6″ sanitary cap from HV-200
6. Clean the 6″ tri-clamp fitting and install the 6″×4″ sanitary reducer with a clean gasket
7. Connect HV-202 to the first purge port and connect a dilute oxygen supply to the second purge port. Make sure the filter is installed on both ports to keep powder out of any detachable lines.
8. Clean the 4″ tri-clamp fitting and put a sanitary gasket in place
9. Ensure that the transfer vessel's 4″ butterfly valve is fully closed
10. Wear appropriate PPE for remainder of procedure when working with reactive powder.
11. Remove the 4″ cap from the transfer vessel
12. Using two people, invert the transfer vessel above the reactor and mate to the 4″ sanitary flange of the reducer. Secure with a 4″ sanitary clamp. Use caution when bringing the transfer vessel to the flange as to not damage the flange
13. Pressure pump the space between HV-200 and the transfer vessel repeatedly with nitrogen to remove air and moisture by cycling HV-202 between N2 and Vent. When finished, leave HV-202 and the auxiliary gas supply valving in the closed position.
14. Open HV-200 and then the transfer vessel valve to transfer the substrate into the reactor.
15. Give powder time to settle and repeat to dislodge any remaining powder from transfer vessel.
16. Close the transfer vessel valve.
17. Close HV-200
18. Use a rotameter to set a low flow rate of dilute oxygen gas and open the dilute oxygen valve to begin pressurizing the space between the reactor and transfer vessel
19. Open the dilute oxygen valve and position HV-202 to direct gas flow out the other side of the adapter to the vent
20. Run dilute oxygen gas through the adapter until passivation is complete. Completion can be estimated by calculating cumulative oxygen flow or monitoring the adapter surface temperature as heat is generated from the reaction.
21. Close the dilute oxygen valve and leave HV-202 open to the vent
22. Disconnect the 4″ sanitary clamp and remove the empty transfer vessel
23. Wipe the inside of all exposed surfaces with a microfiber rag to remove dust.
24. Cap the transfer vessel with a clean gasket
25. Repeat the entire procedure as needed to load the contents of additional transfer vessels into the reactor
26. Disconnect the dilute oxygen line and the LP nitrogen line, then remove the reducer and replace the 6″ cap on the reactor port.
27. Clear the reactor area of any ladders, stairs, tools, or other equipment and then close the safety gate.

### Set and Run Programming

Process development often requires a mix of manual and automatic control, but production requires automating the process as much as possible to guarantee repeatable results. A method of operating a generic coating process is described below. Before using or modifying the provided example programs and recipes, load them into the recipe builder and step through them while reading the following process descriptions which explain the purpose of the different steps.

### Reactive Gas (for Example, Ammonia) Dose

The apparatus and system includes an atmospheric pressure reactive gas delivery option for bulk powder surface treatment. This modification is designed to send a continuous flow of reactive gas through the reactor as it tumbles the powder for long periods of time. Other operating modes are possible to improve reactive gas utilization, such as a dose and hold method. However, for the simplest operation and shortest reaction times continuous flow is preferred. Unlike ALD operation, this process operates at slightly positive pressure (0-15 psig) so the high volume of reactive gas flows directly to an abatement or recycle system without the need for pumping. The positive pressure operation presents a risk for loss of containment of reactive gas in the event of a leak, so it is important to perform a preliminary nitrogen flow test and positive pressure leak check before flowing any reactive gas:

### Positive Pressure Pre-Check:

1. Open XV-200, XV-210, and FV-184 to open the ammonia gas flow path. Leave XV-181, XV-182, PV-210 at the beginning and end of the flow path closed.
2. Open XV-105 to start filling the ammonia flow path and reactor with nitrogen.
3. Close XV-105 when PI-190 measures a pressure of 5 psig.
4. Allow PI-190 and PI-200 to equilibrate.
5. Watch the pressures for 5-10 minutes to make sure that they remain steady. If there is a leak the pressure will drop towards local atmospheric pressure as the pressurized nitrogen gas leaks out of the system.
6. If there are signs of a leak, address the problem and repeat the test.
7. If there are no signs of a leak, gradually open PV-201 to direct the pressurized nitrogen to the reactive gas abatement/recycle system.
8. Reopen XV-105 to flow nitrogen through the reactive gas flow path and out to the reactive gas abatement/recycle system. While nitrogen is flowing, check that pressures are steady and acceptable upstream and downstream of the reactor. Additionally, check that there are no obstructions or obvious leaks in the exhaust lines between the Lithos system and the reactive gas abatement/recycle system.

9. After successfully completing the pre-check, start flowing reactive gas gas with the following steps:
10. Check that HV-181 is closed and HV-180 is open so that MFC 180 is supplied by only reactive gas.
11. Ensure that FV-184, XV-200, XV-201, and PV-201 are all fully open
12. Close XV-105 to stop the flow of nitrogen through the system
13. Open XV-182, set MFC 180 to a flow rate of 25-50 SLPM, and then open XV-181
14. Confirm that reactive gas gas is flowing through the system. If desired, use the high-pressure sampling port on the RGA by opening XV-230 to monitor the reactive gas concentration in the reactor outlet stream
15. Gradually increase the ammonia flow rate to the desired setpoint. After each step, check that pressures are steady and acceptable upstream and downstream of the reactor. Pressure upstream of the reactor must not rise above 15 psig.
16. Once the desired reactive gas flow rate is reached, let the system remain at steady state until the reaction is complete. Periodically monitor the system pressures and perform a filter backpulse to prevent flow restrictions.
17. After the reactive gas flow steps are complete, the system must be purged of residual reactive gas before moving on to ALD or other processes. To complete a reactive gas purge:
18. Close XV-181. When MFC-180 measures close to zero flow, close XV-182 and set the flow rate of MFC-180 to 0 SLPM.
19. Open XV-105 to begin flushing the system with nitrogen gas.
20. Use the high-pressure sampling port on the RGA by opening XV-230 to monitor the reactive gas concentration in the reactor outlet stream
21. When the reactive gas concentration has dropped to low levels (for example, if ammonia evaluating for a threshold ratio of N2:NH3>20:1), close XV-105, XV-200, and PV-201.
22. Open PV-210 to evacuate the reactor and dosing manifold. To pump down more gradually, set PV-210 to only 25% open for the first ~30 seconds or set PIC-210 to a low value (i.e. 10 Torr). When PT-190, PT-200, and PT-210 reach base pressure, wait an additional 120 seconds and then close XV-210 and PV-210. Next, open XV-105 to gradually fill the reactor with nitrogen. When PT-190 reaches a pressure of approximately 350 Torr, close XV-105. Repeat the evacuation and fill steps two more times to complete the purge.

### ALD Preparation

Prior to beginning ALD chemistry, the vaporization vessels must be charged, the reactor system must be purged, and the system must be heated to the proper temperature. Throughout these steps, set the reactor to rotate to ensure the powder is continually mixed and to aid in heat transfer.

To heat the system, adjust the hot oil temperature setpoint to the desired reaction temperature and give the surge vessels and reactor jacket time to equilibrate. If the hot oil is starting at a high temperature, wait until the oil temperature is below 120° C. to open XV-161 to prevent overheating any residual liquid TMA in the TMA Vaporization Vessel V-140. To prevent cold spots that would result in the condensation of precursor vapor, set heating zones HE-128, HE-148, and HE-190 to at least 10° C. above the hot oil temperature.

After heating, purge the system of any residual process gases. To begin, evacuate the reactor and dosing manifold by opening XV-210 and PV-210. When PT-190, PT-200, and PT-210 have reached base pressure, close XV-210 and PV-210. Next, partially open FV-103 to gradually fill the reactor with nitrogen. When PT-190 reaches a pressure of approximately 350 Torr, close FV-103. Repeat the evacuation and fill steps two more times to complete the purge.

After purging, charge the surge vessels with precursor vapor. To begin charging, enter a target pressure setpoint in PIC-124 and PIC-144 for water and TMA, respectively, and open all liquid supply valves feeding the surge vessels. For each precursor, the maximum setpoint is the precursor dew point pressure calculated for a temperature 10° C. below the surge vessel oil return temperature (TE-121 and TE-141).

### ALD Cycle Routine

The traditional operation of ALD coating processes is ubiquitous in the art. For an ordinary system of the prior art, once the system is at the appropriate temperature, the basic process for Al₂O₃ ALD chemistry is to dose TMA vapor, purge TMA vapor, dose water vapor, and purge water vapor. Completing these steps in series completes one Al₂O₃ ALD cycle, and cycles can be repeated as needed to grow a thicker coating on the substrate surface. Throughout the entire ALD process the reactor should be rotating to minimize powder agglomeration and maximize gas-solid mixing. Due to the large quantities of materials to be coated in this industrial-scale ALD system, nitrogen purge gas should also be flowing continually to the pump exhaust to dilute methane produced by the ALD reaction. The large total surface area of the powders to be coated implies that the water and TMA vaporization vessels are repeatedly recharged with precursor during the coating process, so the liquid TMA and water supply valves LV-122, XV-140, XV-141, and LV-142 should remain open during the entire ALD coating process.

### TMA Dose and Hold and Dose Push

It was determined experimentally that the traditional dose and purge approach to ALD cycling in the prior art was insufficient when applying ALD to powders at industrial scales, especially when operating under vacuum conditions. To dose TMA in the Lithos system, first evacuate the reactor and dosing manifold by opening XV-210 and PV-210. To pump down more gradually, set PV-210 to only 25% open for the first ~30 seconds or set PIC-210 to a low value (i.e. 10 Torr). When PT-190, PT-200, and PT-210 have reached base pressure, close XV-210 and PV-210. Next, note the TMA surge vessel pressure measured by PT-144 and then open XV-142 and XV-144 to send TMA vapor to the reactor.

A hold step follows the dose step, which is another tactic taught in the prior art for static dose reactor systems. The hold retains the TMA vapor in the reactor for a programmable amount of time while the powder substrate and precursor vapor mix and react. The exact duration depends on the substrate properties, surface area, and batch size. Often, reaction progress can be estimated by monitoring the pressure rise upstream and downstream of the reactor with PT-190 and PT-200. When the pressure stops rising, the ALD half-reaction is complete. Reaction progress can also be estimated by monitoring the gas composition with the RGA.

However, absent from the prior art is that in an industrial-scale ALD system, the rising reactor pressure from the large volume of reaction byproducts generated during the hold step can trap precursor vapor in the dosing manifold. To force this remaining precursor into the reactor, a short Dose Push step can be implemented. This step involves waiting until a first hold time has elapsed and then briefly opening XV-104 and XV-144 for ~1 second to send a pulse of nitrogen gas through the dosing manifold. After closing these valves, a second hold step is incorporated while the pressure evolution signals are monitored for reaction completion (i.e., a pressure plateau has been reached). In many cases, at least three or four dose push steps may be required to fully cleanse the system.

For the total surface area of many materials at the desired production quantity, a single precursor dose may not provide enough precursor to fully saturate all active sites on the substrate surface (at the desired vaporization vessel and process line operating temperature setpoints and reactor pressure). To completely saturate the surface, a full precursor exposure may require multiple sub-doses. Or conversely, even if a full precursor exposure would not require multiple sub-doses, it is advantageous to separate precursor exposures into sub-cycles to add additional operating parameters to the process than are currently available in prior art ALD systems. To deliver additional sub-doses, repeat the steps in this section until (a) the precursor in a sub-dose is only partially reacted, reaching a target reactor pressure sooner than prior sub-doses, or (b) the ratio between unreacted precursor signals to reaction byproducts in the RGA exceeds a target level. Once the substrate surface is saturated, avoid excess TMA sub-doses as this can overwhelm the abatement system and send unreacted precursor vapor through the pump to the exhaust. To complete sub-doses more quickly, ensure that PIC-144 maintains its setpoint throughout the sub-dose so that the TMA vaporization vessel recharges during the hold step of each dose.

### TMA Purge

The TMA Purge removes residual TMA precursor vapor from the system before the water dose. This process is critical to avoid unwanted CVD and prevent fouling of the equipment. To purge TMA, first evacuate the reactor and dosing manifold by opening XV-210 and PV-210. To pump down more gradually, set PIC-210 to a low value (i.e. 10 Torr). When PT-190, PT-200, and PT-210 have reached base pressure, wait an additional 120 seconds and then close XV-210 and PV-210. Next, open XV-104 and XV-144 to gradually fill the reactor with nitrogen. When PT-190 reaches a pressure of approximately 350 Torr, close these two valves. Repeat the evacuation and fill steps two more times to complete the purge.

After the TMA purge, evacuate the reactor and dosing manifold again and complete a backpulse to clear the filters. To backpulse the filters, close XV-210 and then open XV-205 briefly for ~0.5 seconds. After closing XV-205, evacuate the reactor and dosing manifold once more.

### Water Dose and Hold and Dose Push

To dose water, first evacuate the reactor and dosing manifold by opening XV-210 and PV-210. To pump down more gradually, set PV-210 to only 25% open for the first ~30 seconds or set PIC-210 to a low value (i.e. 10 Torr). When PT-190, PT-200, and PT-210 have reached base pressure, close XV-210 and PV-210. Next, note the water surge vessel pressure measured by PT-124 and then open XV-122 and XV-124 to send water vapor to the reactor. When the PT-124 pressure has dropped by 40% from its initial value, close XV-122 and XV-124. This pressure drops quickly, so it is recommended to use an automated recipe for process control. A hold step follows the dose step. The hold retains the water vapor in the reactor for several minutes while the powder substrate and precursor vapor mix and react. The exact duration depends on the substrate properties, surface area, and batch size. Often, reaction progress can be estimated by monitoring the pressure rise upstream and downstream of the reactor with PT-190 and PT-200. When the pressure stops rising, the ALD half-reaction is complete. Reaction progress can also be estimated by monitoring the gas composition with the RGA (see Section 0).

During the hold step, some water vapor will be trapped in the dosing manifold. To force this precursor into the reactor, a short Dose Push step can be implemented. This step involves waiting until 20-30 seconds of hold time have elapsed and then briefly opening XV-102 and XV-124 for ~1 second to send a pulse of nitrogen gas through the dosing manifold. After closing these valves, resume the hold step.

For most materials, a single water dose will not provide enough precursor to fully saturate all active sites on the substrate surface. To completely saturate the surface, a full water exposure may require multiple sub-doses. To deliver additional sub-doses, repeat the steps in this section until there are clear precursor breakthrough signals in the RGA or sub-dose reaction times become significantly longer. To complete sub-doses more quickly, ensure that PIC-144 maintains its setpoint throughout the sub-dose so that the water surge vessel recharges during the hold step of each dose. Once the substrate surface is saturated, dosing excess water vapor will neutralize excess TMA trapped in the abatement system but overexposing the substrate to water vapor may be undesirable and result in longer purge times.

### Water Purge

The Water Purge removes residual water vapor from the system before the TMA dose. This process is critical to avoid unwanted CVD and prevent fouling of the equipment. To purge water, first evacuate the reactor and dosing manifold by opening XV-210 and PV-210. To pump down more gradually, set PIC-210 to a low value (i.e. 10 Torr). When PT-190, PT-200, and PT-210 have reached base pressure, wait an additional 120 seconds and then close XV-210 and PV-210. Next, open XV-102 and XV-124 to gradually fill the reactor with nitrogen. When PT-190 reaches a pressure of approximately 350 Torr, close these two valves. Repeat the evacuation and fill steps two more times to complete the purge.

After the water purge, evacuate the reactor and dosing manifold again and complete a backpulse to clear the filters. To backpulse the filters, close XV-210 and then open XV-205 briefly for ~0.5 seconds. After closing XV-205, evacuate the reactor and dosing manifold once more.

### Final Ald Cycle

Once the necessary ALD cycles are completed, some TMA precursor vapor remains in the surge vessel. If this TMA will not be needed for a long period of time (weeks to months), an extra partial cycle should be run to consume the excess precursor. To achieve this, shut off the TMA supply valve (PV-144), and perform two or three TMA sub-doses until the surge vessel pressure decreases and no longer delivers TMA vapor to the reactor. Next, slowly pull active vacuum on the reactor and TMA surge vessel by opening XV-142, XV-144, XV-210, and PV-210 (5% open). Once PI-144 reaches base pressure, close XV-142 and XV-144 and make sure that PI-144 remains at base pressure for several minutes. If PI-144 gradually rises, repeat the active vacuum step until it stops. After emptying the TMA surge vessel, perform the typical TMA purge step. Finish the process with several water sub-doses and a water purge to neutralize the reactive surface groups left behind on the powder substrate from the partial TMA dose.

### Material Unloading

This version of the Lithos tool is designed to discharge powder through a 6″ gate valve. On the discharge side of the valve there is a 6″ tri-clamp flange and a pair of filtered purge ports. Powder is discharged to a customer-supplied hopper. The hopper must have an internal volume of at least 160L, an adjustable height or flexible coupling, and a 6″ tri-clamp flange to mate to the discharge valve. The following guidelines can be used as a starting point for unloading a potentially air-sensitive material from the reactor. This procedure should be modified as necessary to fit a customer's facility and process hazards.
1. Ensure system is ready for unload
a. Reactor positioned with discharge port at very bottom of rotation
b. Reactor is cooled below 100° C.
c. Appropriate safeguards in place for entering the reactor zone (reactor stopped, safety gate opened, PPE donned).
d. Reactor has been purged of all precursors and filled with nitrogen to atmospheric pressure
e. Pressure inside hopper is atmospheric
2. Verify hopper is empty and tare weight
3. Position empty hopper under reactor
4. Wear appropriate PPE
5. Ensure unloading valve HV-200 is closed and remove cap
6. Connect the 6″ hopper flex connection to the reactor
7. Connect HV-204 and pressure pump the space between the reactor port and the top hopper valve with nitrogen to remove air and moisture.
8. Open top hopper valve
9. Pressure pump the full volume of the hopper to remove air and moisture if necessary.
10. Open reactor discharge port valve HV-200
11. Attach vibrator to reactor bottom port
12. Allow coated substrate to flow into hopper
13. Close reactor port valve then close top hopper valve
14. Connect dilute oxygen to HV-204 and pressure pump the space between the reactor port and the top hopper valve to passivate residual dust.
15. CAUTION: If the tubing is full of powder during the depressurization of the space bulk powder may be present above the hopper valve.
16. Weigh loaded hopper and confirm by mass balance the reactor is empty

### Inerting

The Lithos tool may include a dedicated inlet to supply dilute oxygen gas (up to 1% O₂ with balance inert gas). The intended use for this supply is to slowly passivate or neutralize residual air-reactive powder in the system. It is preferable to perform dilute O₂ passivation before breaking any connections that could expose reactive powders to air. The dilute O₂ supply enters the system adjacent to the reactive gas supply so that the reactive gas (e.g. Ammonia) MFC can be used to regulate the flow of dilute O₂¹. It is important to isolate each gas supply while the other is open to prevent contamination or reactive gas leaks. A LOTO procedure is recommended to prevent accidentally opening both valves. ¹ If the MFC is calibrated for ammonia gas, for example, the actual flow rate when using dilute O₂ gas (balance nitrogen) will be ~37% higher than the set and measured value.

The following procedure passivates an air-reactive powder in the Lithos system:
1. Close all valves and stop all flows in the system
2. Close and lock the ammonia supply valve, HV-180
3. Pull active vacuum on the reactor by opening XV-210 and PV-210, then open FV-184 and XV-182
4. Set MFC-180 to 50 SLPM and open XV-181 until the measured flow is 0 SLPM to purge remaining reactive gas from the MFC gas supply
5. Close XV-181 and set MFC-180 back to 0 SLPM.
6. Open the dilute O2 supply valve HV-181
7. Reopen XV-181 and slowly flow dilute O2 by adjusting the set point of MFC-180. Continue reactor rotation to ensure good gas-solid contact.
8. Use the RGA to monitor the progress of the O2 passivation reaction. When passivation is complete, oxygen should begin to reach the RGA.
9. Once all powder and surfaces are sufficiently passivated, stop the dilute O2 gas flow and close XV-181.

### End-of-Batch Sequence

After unloading and inerting the system after completing a batch, the tool must be returned to a safe state before opening the reactor for any cleaning or maintenance operations. To reach this state, ensure the following conditions are met:
1. Atmosphere inside reactor is inert gas (or dilute O₂)
2. Pressure inside reactor is atmospheric
3. Reactor is not hot
4. All flows are stopped and all valves are closed
5. No recipe is running

### General Description of Atomic or Molecular Layer Deposition

Atomic layer-controlled growth techniques permit the deposition of coatings of about 0.1 to about 5 angstroms in thickness per reaction cycle, and thus provide a means of extremely fine control over surface coverage or coating thickness. Thicker coatings can be prepared by repeating the reaction sequence to sequentially deposit additional layers of the coating material until the desired coating thickness is achieved.

The coating is deposited in an Atomic Layer Deposition (ALD) or Molecular Layer Deposition (MLD) process. In the ALD/MLD process, the coating-forming reaction is conducted as a series of (typically) two half-reactions. In each of these half-reactions, a single reagent (precursor) is introduced into contact with the substrate surface. Conditions are such that the reagent is in the form of a gas. In most cases, the reagent reacts with functional groups on the surface of the particle and becomes bound to the particle. Because the reagent is a gas, it permeates into pores in the substrate and deposits onto the interior surfaces of the pores as well as onto the exterior surfaces of the substrate. This precursor is designed to react with the surface at all of the available surface sites but not react with itself. In this way, the first reaction occurs to form a single monolayer, or sub-monolayer, and creates a new surface functionality. Excess amounts of the reagent are then removed, which helps to prevent the growth of undesired, larger inclusions of the coating material. Each remaining half-reaction is then conducted in turn, each time introducing a first reagent, allowing it to react at the surface of the particle, and removing excess reagent before introducing the next reagent. Usually, an inert carrier gas is used to introduce the reagents, and the reaction chamber is usually swept with the carrier gas between successive reagent introductions to help remove excess reagents and gaseous reaction products. A vacuum may be pulled during and between successive dosings of reagents, to further remove excess reagents and gaseous reaction products.

After exposure to the first precursor, the surface is then exposed to the second precursor, also typically dispersed in an inert carrier gas. This precursor is designed to react with the functional groups put down in the first reaction step. This reaction also happens until all of the available surface sites are reacted. The second precursor also does not react with itself. Any excess of the second precursor is also removed in an optional inert gas purge step. If the gases are metered properly, the purge step may be unnecessary. This may be at least a 4 step process (precursor 1, purge, precursor 2, purge) to deposit one monolayer of the film which is being grown. This is not meant to imply only a single precursor because some ALD and MLD processes use multiple reactants in a step, for example APTES/H₂O/O₃ for depositing SiO₂. This process is repeated as many times as is necessary to build up the desired film thickness. The ALD/MLD process may start with a “linker” agent, or pre-treatment gas (such as ozone), that facilitates covalent bonding to the surface, or it may end with a terminating agent that may be hydrophobic, hydrophilic, or otherwise engineered for a specific purpose.

For purposes of the present invention, the ALD/MLD process may include only a half reaction, rather than a full cycle. However, at least one full cycle is preferred, more preferably at least five cycles.

A convenient method for applying the coating to a particulate substrate is to form a fluidized or otherwise agitated bed of the particles, and then pass the various reagents in turn through the fluidized bed under reaction conditions. Methods of fluidizing particulate materials are well known, and generally include supporting the particles on a porous plate or screen. A fluidizing gas is passed upwardly through the plate or screen, lifting the particles somewhat and expanding the volume of the bed. With appropriate expansion, the particles behave much as a fluid. Reagents (in gaseous, liquid, or solid phase) can be introduced into the bed for reaction with the surface of the particles. Liquid or solid reagents convert to gaseous form once inside the bed prior to reaction with particles. In this invention, the fluidizing gas also can act as an inert purge gas for removing unreacted reagents and volatile or gaseous reaction products. In addition, the reactions can be conducted at particle surfaces in a rotating cylindrical vessel, a rotating tube, or a vibrating bed. This vibrating bed method is particularly suitable for continuous processes.

Reaction conditions are selected mainly to meet three criteria. The first criterion is that the reagents are gaseous under the conditions of the reaction. Therefore, temperature and pressure conditions are selected such that the reactants volatilize before reaction. The second criterion is one of reactivity. Conditions, particularly temperature, are selected such that the desired reaction between the film-forming reagents (or, at the start of the reaction, the first-introduced reagent and the particle surface) occurs at a commercially reasonable rate. The third criterion is that the substrate is thermally stable, from a chemical standpoint and from a physical standpoint. The substrate should not degrade or react at the process temperature, other than a possible reaction on surface functional groups with one of the ALD precursors at the early stages of the process. Similarly, the substrate should not melt or soften at the process temperature, so that the physical geometry, especially pore structure, of the substrate is maintained. The reactions are generally performed at temperatures from about 270 to 1000 K, preferably from 290 to 450 K, with specific temperatures in each case being below the temperature at which the substrate melts, softens or degrades.

Between successive dosings of the reagents, the particles are subjected to conditions sufficient to remove reaction products and unreacted reagents. This can be done, for example, by subjecting the particles to a high vacuum, such as about 10⁻⁵ Torr or greater, after each reaction step. Another method of accomplishing this, which is more readily applicable for industrial application, is to sweep the particles with an inert purge gas between the reaction steps. This purge gas can also act as a fluidizing medium for the particles and as a carrier for the reagents.

Several techniques are useful for monitoring the progress of the reaction. For example, vibrational spectroscopic studies can be performed using transmission Fourier transform infrared techniques. The deposited coatings can be examined using in situ spectroscopic ellipsometry. Atomic force microscopy studies can be used to characterize the roughness of the coating relative to that of the surface of the substrate. X-ray photoelectron spectroscopy and x-ray diffraction can be used to do depth-profiling and ascertain the crystallographic structure of the coating.

Aluminum oxide coatings are conveniently deposited using trimethylaluminum and water as the precursors, as illustrated by reaction sequence A1/B1. The illustrated reactions are not balanced, and are only intended to show the reactions at the surface of the substrate (i.e., not inter- or intralayer reactions).

$$Substrate - {X H}^{*} + A {l ( {CH}_{3} )}_{3} = Substrate - X - {Al}^{*} - C {H}_{3} + C {H}_{4} ( precursor reaction ) \qquad ( A1 )$$

$$Substrate - X - {Al}^{*} - C {H}_{3} + {H}_{2} O = Substrate - X -- Al - {OH}^{*} + C {H}_{4}$$

$$Substrate - X - Al - {OH}^{*} + {Al ( {CH}_{3} )}_{3} = Substrate - X - Al - O - A - {1}^{*} - {CH}_{3} + C {H}_{4} \qquad ( B1 )$$

In reactions A1/B1, X is typically oxygen, nitrogen or sulfur, and the asterisk (*) represents the surface species at which the next half-reaction can occur. An aluminum oxide film is built up by repeating reactions A1 and B1 in alternating fashion, until the desired coating thickness is achieved. Aluminum oxide films tend to grow at a rate of approximately 0.1 nm/cycle using this reaction sequence.

Titanium oxide coatings are conveniently deposited using titanium tetrachloride and water and/or hydrogen peroxide as the precursors, as illustrated by reaction sequence A2/B2. As before, the illustrated reactions are not balanced, and are only intended to show the reactions at the surface of the particles (i.e., not inter- or intralayer reactions).

$$Substrate - {X H}^{*} + {TiCl}_{4} = Substrate - X -- {Ti}^{*} - C {H}_{3} + HCl ( precursor reaction ) \qquad ( A2 )$$

$$Substrate - X -- {Ti}^{*} - {Cl}_{3} + {H}_{2} {O}_{2} = Substrate - X - T - {i}^{*} - OH + HCl + {Cl}_{2}$$

$$Substrate - X - {Ti}^{*} - OH + {TiCl}_{4} \qquad ( B2 )$$

$$Substrate - X - Ti - O - {Ti}^{*} - {Cl}_{3} + - HCl$$

In reactions A2/B2, X is typically oxygen, nitrogen or sulfur, and the asterisk (*) represents the surface species at which the next half-reaction can occur. A titanium oxide film is built up by repeating reactions A2 and B2 in alternating fashion, until the desired coating thickness is achieved. Titanium oxide films tend to grow at a rate of approximately 0.05-0.1 nm/cycle using this reaction sequence.

As is known for ALD/MLD processes, the order can be AB, ABC, ABCD, ABCDABABCD, or any desired order provided that the chemical entities react with each other in the desired order. Each of the reactants has at least two reactive moieties (this includes the possibility that the reactant is modifiable to have two reactive moieties such as having a first reactive moiety and a second reactive moiety that is temporarily blocked by a protecting group or requires activation for subsequent reaction such as UV activation). In some preferred embodiments, the reactants have exactly two reactive moieties since higher numbers of reactive groups may lead to lower packing density. In some preferred embodiments, the films have at least three repeating units (e.g., ABABAB), or at least 5, or at least 10, or at least 50, and sometimes in the range of 2 to 1000, or 5 to 100. By “reactive” it is meant under normal MLD conditions and commercially relevant timescales (for example, at least 50% reacted within 10 hours under appropriate reaction conditions). For control of film quality, the reactants may be singly reactive during each step of the MLD process to avoid reacting twice to the surface, and the reactants should not self-react and condense onto the surface.

In some preferred embodiments, the reactive moieties for Reactant A may comprise: isocyanates (R—NCO), acrylates, carboxylic acids, esters, epoxides, amides and amines, and combinations thereof. In some preferred embodiments, Reactant A comprises a diisocyanate, a diacrylate, a dicarboxylic acid, a diester, diamide or a diamine. In some preferred embodiments, the reactive moieties on Reactant B comprise: alcohols or amines, and combinations thereof. In some preferred embodiments, Reactant B comprises a diol, an amine alcohol, or a diamine.

An inorganic layer applied to the particle in a first step preferably becomes covalently bonded to the substrate. Covalent bonding can occur when the first-to-be-applied precursor compound reacts under the conditions of the atomic layer deposition process with a functional group on the surface of the substrate. Examples of such functional groups are, for example, hydroxyl, carbonyl, carboxylic acid, carboxylic acid anhydride, carboxylic acid halide, primary or secondary amino.

Some ALD coatings are aluminum oxide and/or titanium oxide coatings. “Aluminum oxide” is used herein to designate a coating that is made up substantially entirely of aluminum and oxygen atoms, without reference to the specific stoichiometry. In many cases, it is expected that an aluminum oxide coating will correspond somewhat closely to the empirical structure of alumina, i.e., Al₂O₃, although deviations from this structure are common and may be substantial. “Titanium oxide” is used herein to designate a coating that is made up substantially entirely of titanium and oxygen atoms, without reference to the specific stoichiometry. In most cases, it is expected that a titanium oxide coating will correspond closely to the empirical structure of titania, i.e., TiO₂, although deviations from this structure are common and may be substantial.

Except for the case of a half-reaction included in the broader aspects of the present invention, the atomic layer deposition process is characterized in that at least two different reactants are needed to form the coating layer. The reactants are introduced into the reaction zone individually, sequentially and in the gas phase. Excess amounts of reactant are removed from the reaction zone before introducing the next reactant. Reaction by-products are removed as well, between successive introductions of the reagents. This procedure ensures that reactions occur at the surface of the substrate, rather than in the gas phase.

A purge gas is typically introduced between the alternating feeds of the reactants, in order to further help to remove excess reactants. A carrier gas, which is usually but not necessarily the same as the purge gas, generally (but not always necessarily) is introduced during the time each reactant is introduced. The carrier gas may perform several functions, including (1) facilitating the removal of excess reactant and reaction by-products and (2) distributing the reactant through the reaction zone, thereby helping to expose all surfaces to the reactant. The purge gas does not react undesirably with the ALD reactants or the deposited coating, or interfere with their reaction with each other at the surface of the substrate. Temperature and pressure conditions will depend on the particular reaction system, as it remains necessary to provide gaseous reactants. As is known for ALD/MLD processes, the temperature should be high enough to enable reactants in the gas phase but not so high that the product degrades.

The coating may comprise any coating that can be applied by molecular or atomic layer deposition. Some well-known coatings that can be applied to the metallic or other material core particle may comprise: metal, semi-metal, non-metal or metalloid oxides or mixed oxides (e.g., Al₂O₃, TiO₂, ZnO, ZrO₂, SiO₂, HfO₂, Ta₂O₅, LiNbₓO_{y}), nitrides (e.g., TIN, TaN, W₂N, TiY₂N), sulfides (e.g., ZnS, CdS, SnS, WS₂, MoS₂, ZnIn₂S₄), and phosphides (e.g., GaP, InP, Fe_{0.5}Co_{0.5}P). Some lesser known materials that can be applied to the core particle may comprise: transition metals (e.g., of Al, Cu, Co, W, Cr, Fe, Zn, Zr, Pt, Pd), metal fluorides (e.g., AlF₃, MgF₂, ZnF₂), oxy fluorides and oxy nitrides of transition metals, lanthanides in either elemental, oxide, fluoride, nitride, boride, or sulfide form (e.g., Y, YN, La₂O₃, LaF₃, Nb, Dy₂₀₃, Nd, LaB₆, La₂S₃ etc), borides (e.g., TiB₂), carbides (e.g., B₄C, WC), silanes, silicides and other silicon containing materials, carbon-containing materials including, but not limited to, polymers (e.g., polyamides, polyethylenes, polyamides, polyureas, polyurethanes), hydrocarbons, polymers or fragments of amino acids or other biological-related molecules and polymers, and other materials), fluorinated polymers (e.g., fluoro or perfluoro-polyamides, -polyethylenes, -polyamides, -polyureas, -urethanes, -hydrocarbons). This coating is highly uniform over the particle; preferably, there is no more than a 20%, more preferably no more than 10%, or no more than 5% variation in coating thickness over the surface of the particle. This high level of uniformity is a characteristic of the ALD/MLD process. Particles coated by ALD/MLD are distinguishable from particles coated by other methods by 1) the uniformity of film thickness and 2) the lack of change in particle size distribution of the individual core particles, which are not possible with other techniques.

Coatings, on core powders, typically have a thickness in the range of 0.1 to 100 nm; preferably 0.2 to 50 nm; more preferably 0.5 to 10 nm, or 0.2 nm to 2 nm. Coating thickness can be measured by transmission electron microscopy (TEM). An ALD/MLD coating may cover 20% of the surface or less, or at least 20% of the surface, or at least 60% of the surface, or at least 80%, or at least 95% and still more or at least 99% of the surface area of the particles.

1. An atomic layer deposition system for exposing a first reactive precursor and a second reactive precursor to a plurality of particles having a known total surface area comprising:
a first vaporization vessel (V-120) comprising the first reactive precursor, a first thermal control system having a first thermal controller adapted to control an operating temperature of the first vaporization vessel V-120, and a first pressure transducer PT-124 to measure an operating pressure of the first vaporization vessel V-120;
a first volume element (VE-12X) defined by a pipe volume contained between a first computer-controlled valve (XV-122), a second computer-controlled valve (XV-124) and a third computer-controlled valve (XV-102);
a second vaporization vessel (V-140) comprising the second reactive precursor and a second thermal controller adapted to control an operating temperature of the second vaporization vessel V-140, and a second pressure transducer PT-144 adapted to measure an operating pressure of the second vaporization vessel V-140;
a second volume element (VE-14X) defined as a pipe volume contained between a fourth computer-controlled valve (XV-142), a fifth computer-controlled valve (XV-144) and a sixth computer-controlled valve (XV-104);
an inert gas delivery system in fluid communication with both: a first volume element (VE-12X) when the third computer-controlled valve (XV-102) is in an open position, and the second volume element (VE-14X) when the sixth computer-controlled valve (XV-104) is in an open position; and
a reactor (R-200) having a gas inlet, a gas outlet, and a gate valve for loading and unloading the plurality of particles having a known total surface area, and having a third thermal control system having a means of controlling the operating temperature of the reactor, and a third pressure transducer to measure the operating pressure of the reactor;
wherein the first vaporization vessel V-120 is in fluid communication with the first volume element (VE-12X) when the first computer-controlled valve XV-122 is in an open position, and wherein the second vaporization vessel V-140 is in fluid communication with the second volume element (VE-14X) when the fourth computer-controlled valve XV-142 is in an open position;
wherein the first volume element is in fluid communication with the reactor when the second computer-controlled valve is in an open position, and wherein the second volume element is in fluid communication with the reactor when the fifth computer-controlled valve is in an open position; and
wherein the second computer-controlled valve and the fifth computer-controlled valve cannot be in an open position simultaneously, wherein the first computer-controlled valve and the third computer-controlled valve cannot be in an open position simultaneously, wherein the fourth computer-controlled valve and the sixth computer-controlled valve cannot be in an open position simultaneously.

2. The atomic layer deposition system of claim 1, wherein the first vaporization vessel further comprises an inlet port for filling the first reactive precursor, a first liquid level sensor positioned at or near the bottom of the first vaporization vessel, and a first dew point control system in electrical signal communication with the first thermal control system, the first pressure transducer the first liquid level sensor, the third thermal control system, and the third pressure transducer.

3. The atomic layer deposition system of claim 2, wherein the second vaporization vessel further comprises an inlet port for filling the second reactive precursor, a second liquid level sensor positioned at or near the bottom of the second vaporization vessel, and a second dew point control system in electrical signal communication with the second thermal control system, the second pressure transducer the second liquid level sensor, the third thermal control system, and the third pressure transducer.

4. The atomic layer deposition system of claim 1, further comprising a seventh computer-controlled valve interposed between the inert gas delivery system and the reactor, wherein the seventh computer-controlled valve is able to be modulated between an open state (100%), a closed state (0%), and partial states (1% to 99%).

5. The atomic layer deposition system of claim 1, further comprising an eighth computer-controlled valve positioned after the gas outlet of the reactor, wherein the eighth computer-controlled valve is able to be modulated between an open state (100%), a closed state (0%), and partial states (1% to 99%).

6. The atomic layer deposition system of claim 1, wherein the gas inlet and gas outlet of the reactor are positioned coaxially to each other.

7. The atomic layer deposition system of claim 1, wherein the reactor is rotatable horizontally at a controllable frequency ranging from 0.5 to 30 revolutions per minute, and along the same axis as the coaxial gas inlet and gas outlet, and wherein the coaxial gas inlet and gas outlet rotate with the reactor.

8. The atomic layer deposition system of claim 1, wherein the volume of the reactor is at least 25 Liters, at least 50 Liters, at least 100 Liters, or at least 250 Liters.

9. The atomic layer deposition system of claim 8, wherein the volume of each vaporization vessel is 40% to 60% of the volume of the reactor.

10. A method for applying a coating onto a plurality of particles having a known total surface area in a reactor comprising a sub-cycle comprising the steps of:
administering from a dosing source, a first precursor dose into the reactor at a first controlled precursor temperature, which defines the first precursor pressure, for a first time period;
terminating the first precursor dose administration and isolating the reactor from the dosing source and vacuum pump, and applying a first static hold for a second time period;
administering a first dose push comprising inert gas into the reactor at an inert gas pressure that is at least 100 Torr higher than the first precursor pressure at the first controlled precursor temperature, for a third time period;
terminating the first dose administration and isolating the reactor from the dosing source and vacuum, and applying a second static hold for a fourth time period; and
repeating the steps of the sub-cycle a first plurality of times, wherein the pressure of the reactor during the fourth time period of each repeated sub-cycle is at least 50 Torr greater than the pressure of the reactor during the fourth time period of each immediately preceding sub-cycle.

11. The method of claim 10, wherein the sub-cycles are repeated a second plurality of times to apply a second plurality of ALD cycles on the plurality of particles having a known total surface area.

12. A method for applying an ALD coating onto a plurality of particles having a known total surface area in a reactor operatively connected to a residual gas analyzer (RGA) comprising a sub-cycle comprising the steps of:
administering from a dosing source, a first precursor dose into the reactor at a first controlled precursor temperature, which defines the first precursor pressure, for a first time period and independently monitoring the RGA signals of the ALD reaction product and the precursor, wherein the maximum height of the RGA signal of the ALD reaction product is defined as S_{Y} where Y=1, and the first time period is defined as t_{Y} where Y=1, the time between the initial rise of the RGA signal of the ALD reaction product and the initial rise of the RGA signal of the precursor;
terminating the first precursor dose administration and isolating the reactor from the dosing source and vacuum pump, and applying a first static hold for a second time period;
administering a first dose push comprising inert gas into the reactor at an inert gas pressure that is less than that of the first precursor pressure at the first controlled precursor temperature, for a third time period;
terminating the first dose administration and isolating the reactor from the dosing source and vacuum, and applying a second static hold for a fourth time period; and
repeating the steps of the sub-cycle for Y times where Y is at least two, and until the product of S_{Y}·t_{Y} during the Yth sub-cycle is <5% of the product of S₁·t_{1·}

13. The method of claim 12, wherein the Y sub-cycles are repeated Z times to apply Z ALD cycles on the plurality of particles having a known total surface area.

14. The method of claim 12, wherein with the second time period and the fourth time period of each Yth sub-cycle are reduced until the summation of ΣS_{Y}·t_{Y·} during any ALD cycle deviates by more than 5% of the summation of ΣS_{Y}·t_{Y·} during the immediately preceding ALD cycle.

15. The method of claim 13, further comprising a second precursor wherein the Z ALD cycles include the Y sub-cycles of claim 12 as applied to the first precursor, followed by the X sub-cycles of claim 10 as applied to the second precursor.

16. The method of claim 15, wherein the first precursor comprises a metal, semi-metal, non-metal or metalloid element that forms the cation of the ALD coating.

17. The method of claim 15, wherein the second precursor comprises oxygen, nitrogen, fluorine, carbon, phosphorous or sulfur and forms the anion of the ALD coating.

18. The method of claim 10, carried out in the atomic layer deposition system of claim 1.

19. The method of claim 12, carried out in the atomic layer deposition system of claim 1.

20. The method of claim 15, carried out in the atomic layer deposition system of claim 1.
